(19) United States
(12) Patent Application Publication
(10) Pub. No.: US 2026/0324420 A1
(43) Pub. Date: Oct. 15, 2026

(54) SEMICONDUCTOR DEVICE, METHOD FOR MANUFACTURING SEMICONDUCTOR DEVICE, INVERTER DEVICE, AND VEHICLE

(71) Applicant: ROHM CO., LTD., Kyoto-shi (JP)

(72) Inventors: Takayuki ISHIHARA, Kyoto-shi (JP); Tomohiro YASUNISHI, Kyoto-shi (JP)

(21) Appl. No.: 19/694,415

(22) Filed: Jun. 1, 2026

Related U.S. Application Data
(63) Continuation of application No. PCT/JP2024/041118, filed on Nov. 20, 2024.

(30) Foreign Application Priority Data
Dec. 7, 2023 (JP) 2023-206633

(51) Int. Cl. H10W 40/20; H10W 40/00; H10W 72/00; H10W 90/00; H10W 90/10

(52) U.S. Cl. CPC H10W 40/235; H10W 40/03; H10W 90/10; H10W 90/736; H10W 90/766; H10W 72/886

(57) ABSTRACT

A semiconductor device includes a heat dissipation member, a base material including a heat dissipation layer facing the heat dissipation member in a first direction, a first conductive layer positioned opposite to the heat dissipation member with respect to the base material and bonded to the base material, a first semiconductor element bonded to the first conductive layer, and a bonding layer bonding the heat dissipation member to the heat dissipation layer. The bonding layer includes a sintered body of metal particles. The bonding layer is provided with a void portion penetrating the bonding layer in the first direction.

### TECHNICAL FIELD

The present disclosure relates to a semiconductor device, a method for manufacturing the semiconductor device, an inverter device including the semiconductor device, and a vehicle equipped with the semiconductor device.

### BACKGROUND

Conventionally, semiconductor devices equipped with semiconductor elements having switching functions (such as MOSFETs and IGBTs) are widely known and are primarily used for power conversion. WO 2023/047890 discloses an example of such a semiconductor device. The semiconductor device disclosed in this document includes a sealing resin covering the semiconductor element, a heat dissipation member, and a mounting member. The mounting member is a leaf spring. A sealing resin is attached to the heat dissipation member via the mounting member. The sealing resin is sandwiched between the heat dissipation member and the mounting member.

In addition to the semiconductor device disclosed in WO 2023/047890, there are cases where a base material is bonded to the heat dissipation member via a bonding layer. The base material carries the semiconductor element and is exposed from the sealing resin. The bonding layer is, for example, a sintered body containing metal particles. In this case, the bonding layer is formed by sintering. As a result, shear stress caused by the heat of sintering occurs at both the interface between the bonding layer and the heat dissipation member and the interface between the bonding layer and the base material. If the concentration of this shear stress becomes excessive, the base material may delaminate from the heat dissipation member when the bonding layer is cooled to room temperature. If such delamination occurs, a gap forms between the heat dissipation member and the base material, causing the thermal resistance to increase. Consequently, there is a concern that the heat dissipation performance of the semiconductor device will deteriorate.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a plan view corresponding to FIG. 2, showing through the sealing resin.

FIG. 4 is a partial enlarged view of FIG. 3.

FIG. 5 is a plan view corresponding to FIG. 2, showing through the first conductive connection member, in which the sealing resin and the second conductive connection member are omitted.

FIG. 6 is a right side view of the semiconductor device shown in FIG. 1.

FIG. 7 is a bottom view of the semiconductor device shown in FIG. 1.

FIG. 8 is a cross-sectional view along line VIII-VIII in FIG. 3.

FIG. 9 is a cross-sectional view along line IX-IX in FIG. 3.

FIG. 10 is a partial enlarged view of the first semiconductor element and its surrounding area shown in FIG. 9.

FIG. 11 is a partial enlarged view of the second semiconductor element and its surrounding area shown in FIG. 9.

FIG. 12 is a cross-sectional view along line XII-XII in FIG. 3.

FIG. 13 is a cross-sectional view along line XIII-XIII in FIG. 3.

FIG. 14 is a bottom view corresponding to FIG. 7, in which a heat dissipation member is omitted.

FIG. 15 is a bottom view of a semiconductor device according to a first variation of the first embodiment of the present disclosure, in which the heat dissipation member is omitted.

FIG. 16 is a bottom view of a semiconductor device according to a second variation of the first embodiment of the present disclosure, in which the heat dissipation member is omitted.

FIG. 17 is a cross-sectional view illustrating a first step of the manufacturing process for the semiconductor device shown in FIG. 1.

FIG. 18 is a cross-sectional view illustrating a second step of the manufacturing process for the semiconductor device shown in FIG. 1.

FIG. 19 is a cross-sectional view illustrating a third step of the manufacturing process for the semiconductor device shown in FIG. 1.

FIG. 20 is a cross-sectional view illustrating a fourth step of the semiconductor device manufacturing process shown in FIG. 1.

FIG. 21 is a plan view of an inverter device equipped with the semiconductor device shown in FIG. 1.

FIG. 22 is a partial enlarged view of FIG. 21.

FIG. 23 is a front view of the inverter device shown in FIG. 21 and corresponds to FIG. 22.

FIG. 24 is a partial enlarged cross-sectional view of the wiring substrate shown in FIG. 22.

FIG. 25 is a circuit block diagram of the inverter device shown in FIG. 21.

FIG. 26 is a partial enlarged view of FIG. 25.

FIG. 27 is a circuit block diagram of each of a plurality of drive circuits, which are elements of the circuit shown in FIG. 25.

FIG. 28 is a schematic diagram of a vehicle equipped with the semiconductor device shown in FIG. 1.

FIG. 29 is a bottom view of the semiconductor device according to the second embodiment of the present disclosure, in which the heat dissipation member is omitted.

FIG. 30 is a bottom view of a semiconductor device according to a variation of the second embodiment of the present disclosure, in which the heat dissipation member is omitted.

FIG. 31 is a bottom view of a semiconductor device according to a third embodiment of the present disclosure, in which the heat dissipation member is omitted.

FIG. 32 is a bottom view of a semiconductor device according to a variation of the third embodiment of the present disclosure, in which the heat dissipation member is omitted.

FIG. 33 is a bottom view of a semiconductor device according to a fourth embodiment of the present disclosure, in which the heat dissipation member is omitted.

FIG. 34 is a bottom view of a semiconductor device according to a variation of the fourth embodiment of the present disclosure, in which the heat dissipation member is omitted.

FIG. 35 is a bottom view of a semiconductor device according to a fifth embodiment of the present disclosure, in which the heat dissipation member is omitted.

FIG. 36 is a cross-sectional view of the semiconductor device shown in FIG. 35, corresponding to FIG. 9.

### DETAILED DESCRIPTION OF EMBODIMENTS

The details of the present disclosure will be described with reference to the accompanying drawings.

### First Embodiment

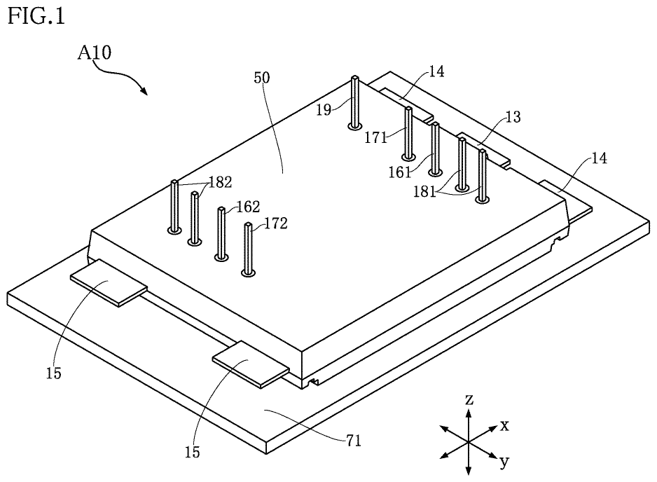

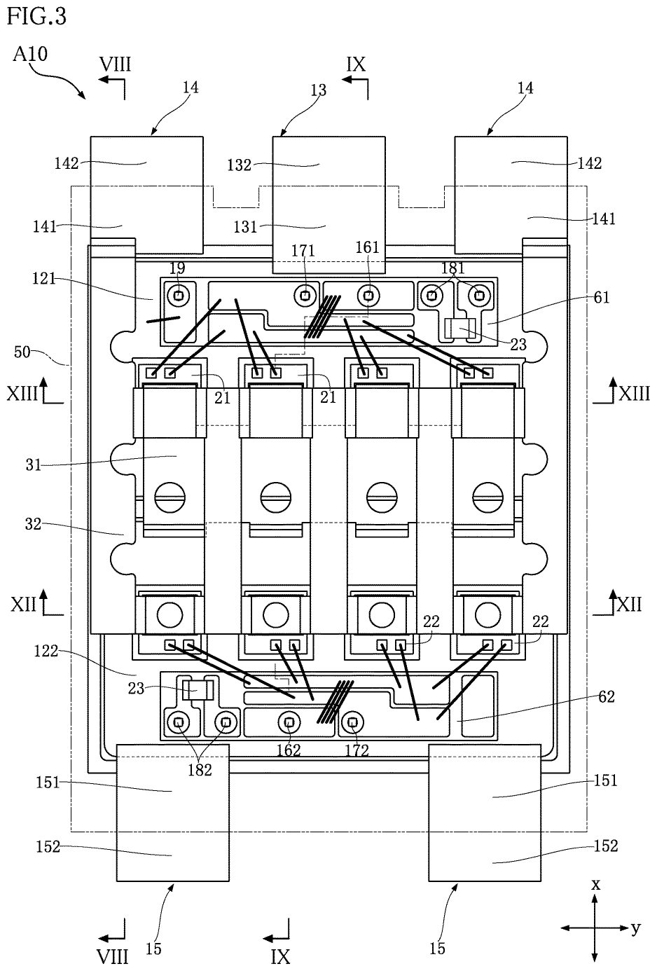

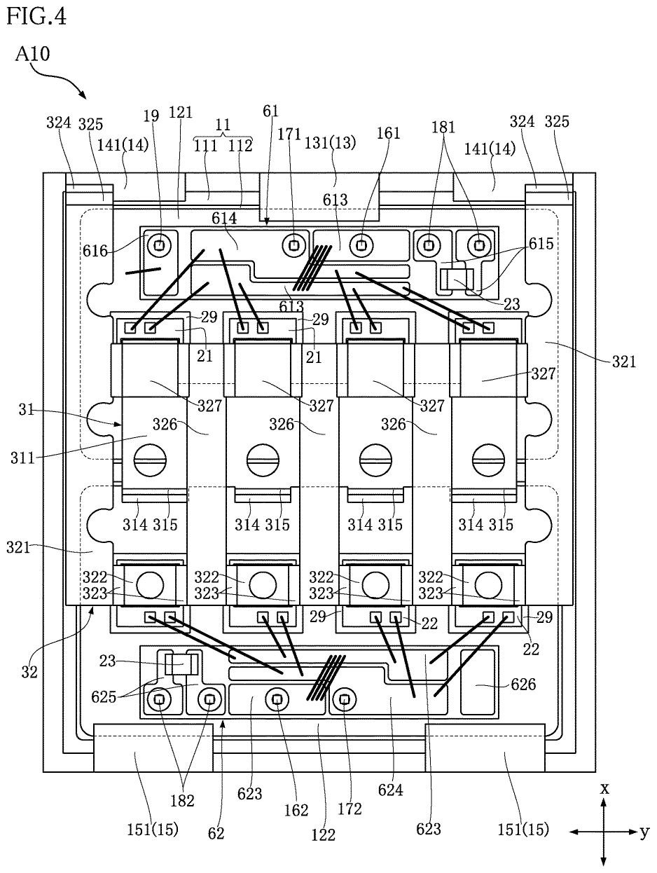

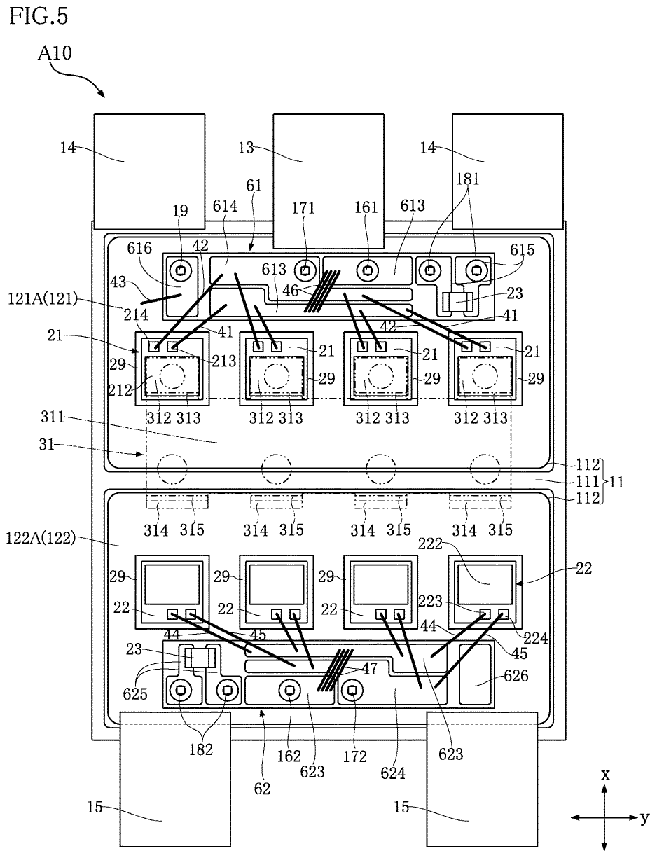

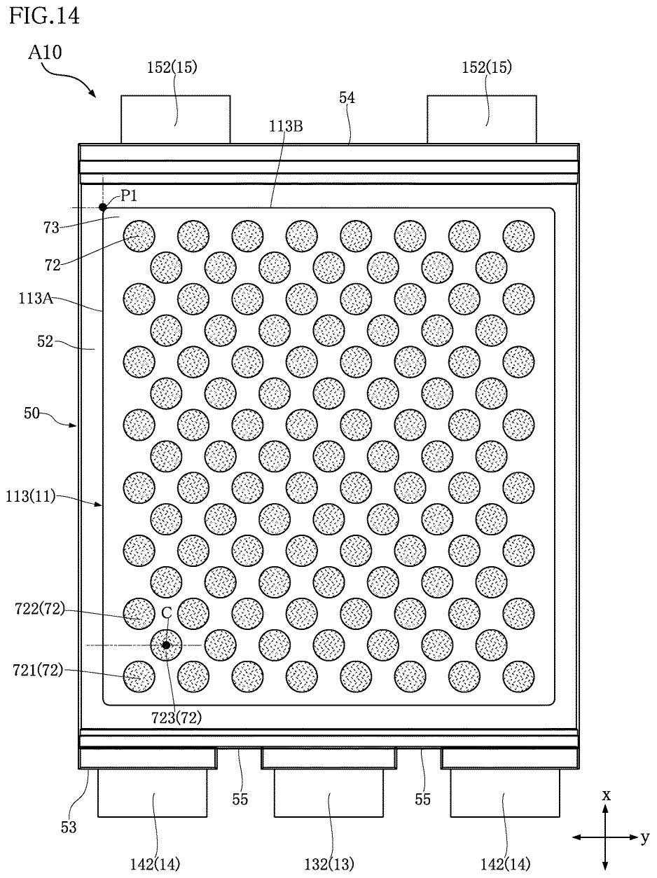

With reference to FIGS. 1 to 14, a semiconductor device A10 according to a first embodiment of the present disclosure will be described. The semiconductor device A10 includes a base material 11, a first conductive layer 121, a second conductive layer 122, a first power terminal 13, two second power terminals 14, two third power terminals 15, a plurality of first semiconductor elements 21, a plurality of second semiconductor elements 22, a first conductive connection member 31, a second conductive connection member 32, a sealing resin 50, a heat dissipation member 71, and a bonding layer 72. Furthermore, the semiconductor device A10 includes a first signal terminal 161, a second signal terminal 162, a third signal terminal 171, a fourth signal terminal 172, two fifth signal terminals 181, two sixth signal terminals 182, a seventh signal terminal 19, two thermistors 23, a first wiring 61, and a second wiring 62. Here, in FIGS. 3 and 4, for ease of understanding, the sealing resin 50 is shown as being transparent. In FIG. 3, the sealing resin 50 shown as being transparent is indicated by a two-dot chain line. In FIG. 5, for ease of understanding, the first conductive connection member 31 is shown as being transparent, and the second conductive connection member 32 and the sealing resin 50 are omitted. In FIG. 14, for ease of understanding, the heat dissipation member 71 is omitted.

In the description of the semiconductor device A10, for convenience, the normal direction of the first main surface 121A of the first conductive layer 121, which will be described later, is referred to as the “first direction z”, for example. Furthermore, the direction orthogonal to the first direction z is referred to as the “second direction x”, for example. Furthermore, the direction orthogonal to the first direction z and the second direction x is referred to as the “third direction y”, for example.

The semiconductor device A10 converts DC power input to the first power terminal 13 and the two second power terminals 14 into AC power using a plurality of first semiconductor elements 21 and a plurality of second semiconductor elements 22. The converted AC power is input to a power supply target (e.g., the motor 89 described below) from each of the two third power terminals 15.

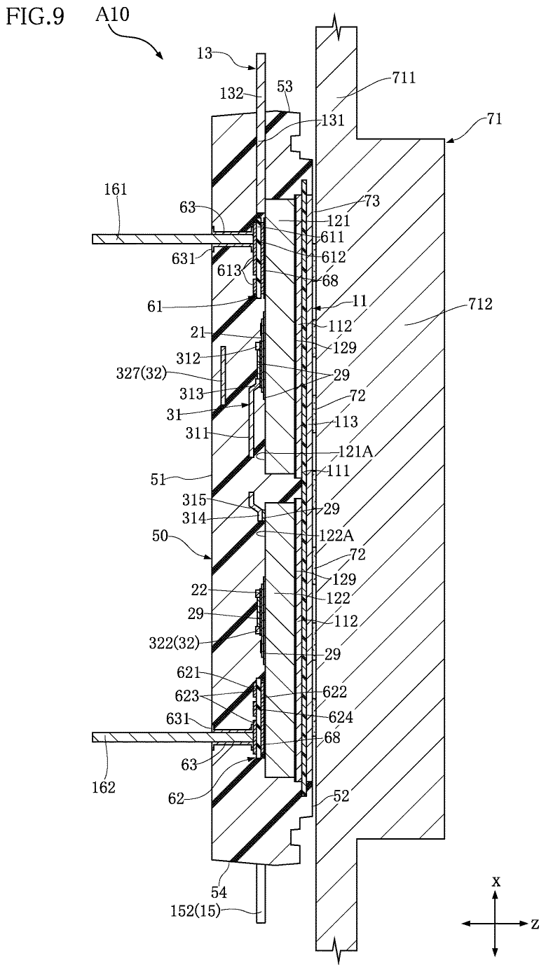

As shown in FIGS. 9 to 11, the base material 11 is located on the side opposite to the plurality of first semiconductor elements 21 and the plurality of second semiconductor elements 22, with respect to the first conductive layer 121 and the second conductive layer 122 in the first direction z. The base material 11 supports the first conductive layer 121 and the second conductive layer 122. In the semiconductor device A10, the base material 11 is composed of a substrate formed, for example, by active metal brazing (AMB). As shown in FIGS. 9 to 11, the base material 11 includes an insulating layer 111, two support layers 112, and a heat dissipation layer 113. The base material 11 is covered by a sealing resin 50, except for a portion of the heat dissipation layer 113.

As shown in FIGS. 9 to 11, the insulating layer 111 includes a portion interposed between the support layers 112 and the heat dissipation layer 113 in the first direction z. The insulating layer 111 is made of a material with relatively high thermal conductivity. The insulating layer 111 is made, for example, of a ceramic containing aluminum nitride (AlN). In addition to ceramics, the insulating layer 111 may also be composed of an insulating resin sheet. The dimension in the first direction z of the insulating layer 111 is smaller than the dimension in the first direction z of each of the first conductive layer 121 and the second conductive layer 122.

As shown in FIGS. 9 to 11, the two support layers 112 are located between the insulating layer 111, and the first conductive layer 121 and the second conductive layer 122 in the first direction z. The support layers 112 are spaced apart from each other in the second direction x. The support layers 112 contain copper (Cu). As shown in FIG. 5, as viewed in the first direction z, the support layers 112 are located inward of the periphery of the insulating layer 111.

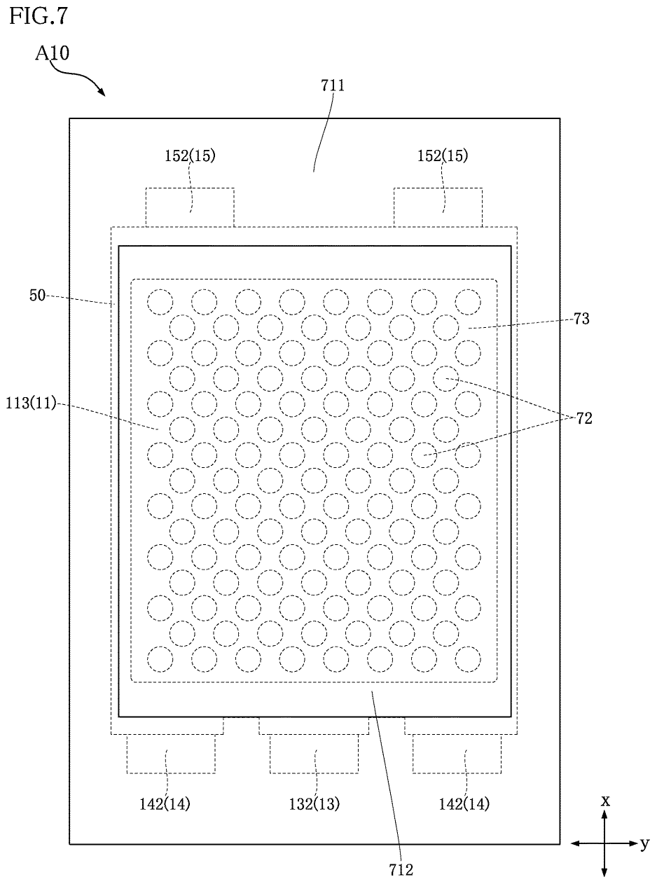

As shown in FIGS. 9 to 11, the heat dissipation layer 113 is located on the side opposite to the two support layers 112 with respect to the insulating layer 111 in the first direction z. As shown in FIG. 7, the heat dissipation layer 113 is exposed from the sealing resin 50. The heat dissipation layer 113 contains copper. The dimension in the first direction z of the heat dissipation layer 113 is larger than the dimension in the first direction z of the insulating layer 111. As viewed in the first direction z, the heat dissipation layer 113 is located inward of the periphery of the insulating layer 111.

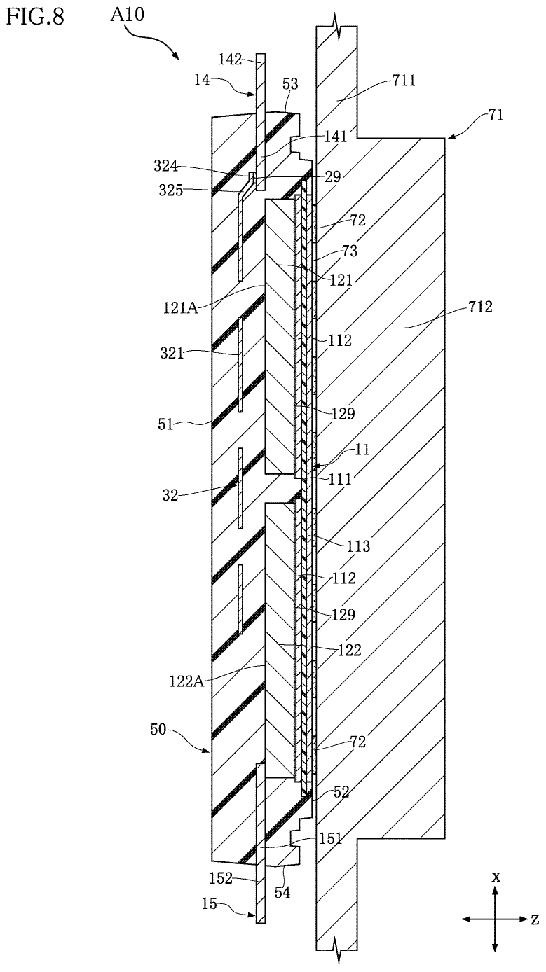

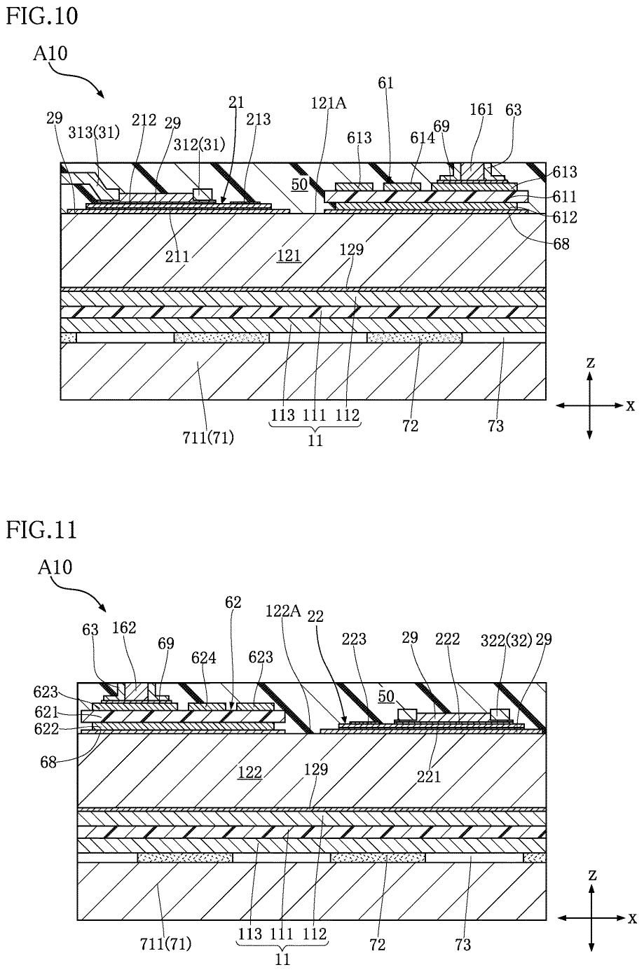

As shown in FIGS. 9 to 11, the first conductive layer 121 and the second conductive layer 122 are bonded to the base material 11. The first conductive layer 121 and the second conductive layer 122 contain copper. The first conductive layer 121 and the second conductive layer 122 are spaced apart from each other in the second direction x. As shown in FIGS. 8 and 9, the first conductive layer 121 has a first main surface 121A facing the first direction z. The first main surface 121A faces the plurality of first semiconductor elements 21. As shown in FIG. 10, the first conductive layer 121 is bonded to one of the two support layers 112 via a first bonding layer 129. The first bonding layer 129 is, for example, solder. As shown in FIGS. 8 and 9, the second conductive layer 122 has a second main surface 122A facing the same side as the first main surface 121A in the first direction z. The second main surface 122A faces the plurality of second semiconductor elements 22. As shown in FIG. 11, the second conductive layer 122 is bonded to the other one of the two support layers 112 via the first bonding layer 129.

As shown in FIGS. 5 and 9, the plurality of first semiconductor elements 21 are bonded to the first main surface 121A of the first conductive layer 121. The plurality of first semiconductor elements 21 are arranged along the third direction y. The plurality of second semiconductor elements 22 are bonded to the second main surface 122A of the second conductive layer 122. The plurality of second semiconductor elements 22 are arranged along the third direction y. The plurality of first semiconductor elements 21 and the plurality of second semiconductor elements 22 are, for example, MOSFETs (Metal-Oxide-Semiconductor Field-Effect Transistors). Alternatively, the plurality of first semiconductor elements 21 and the plurality of second semiconductor elements 22 may be switching elements such as IGBTs (Insulated Gate Bipolar Transistors). Furthermore, the plurality of first semiconductor elements 21 may be configured to include a plurality of switching elements and a plurality of freewheeling diodes connected in parallel individually with these switching elements. Similarly, the plurality of second semiconductor elements 22 may also be configured to include a plurality of switching elements and a plurality of freewheeling diodes connected in parallel individually with these switching elements. The freewheeling diodes are, for example, Schottky barrier diodes. In the description of the semiconductor device A10, the plurality of first semiconductor elements 21 and the plurality of second semiconductor elements 22 are assumed to be n-channel type, vertical-structure MOSFETs. The plurality of first semiconductor elements 21 and the plurality of second semiconductor elements 22 include a compound semiconductor substrate. The compound semiconductor substrate contains silicon carbide (SiC).

As shown in FIGS. 5 and 10, each of the plurality of first semiconductor elements 21 has a first electrode 211, a second electrode 212, a first gate electrode 213, and a first detection electrode 214.

As shown in FIG. 10, the first electrode 211 faces the first main surface 121A of the first conductive layer 121. A current corresponding to the electrical power prior to conversion by the first semiconductor element 21 flows through the first electrode 211. That is, the first electrode 211 corresponds to the drain electrode of the first semiconductor element 21. The first electrode 211 is conductively bonded to the first main surface 121A via the conductive bonding layer 29. Consequently, the first electrode 211 of each of the plurality of first semiconductor elements 21 is electrically connected to the first conductive layer 121. The conductive bonding layer 29 is a sintered body of metal particles containing silver (Ag) or the like. Alternatively, the conductive bonding layer 29 may be solder. Furthermore, the conductive bonding layer 29 may be liquid metal.

As shown in FIG. 10, the second electrode 212 is located on the side opposite to the side facing the first main surface 121A of the first conductive layer 121 in the first direction z. Therefore, the first electrode 211 and the second electrode 212 are located on opposite sides of each other in the first direction z. A current corresponding to the electrical power converted by the first semiconductor element 21 flows through the second electrode 212. That is, the second electrode 212 corresponds to the source electrode of the first semiconductor element 21.

As shown in FIG. 10, the first gate electrode 213 is located on the side opposite to the side facing the first main surface 121A of the first conductive layer 121 in the first direction z. Therefore, the first gate electrode 213 is located on the same side as the second electrode 212 in the first direction z. A gate voltage for driving the first semiconductor element 21 is applied to the first gate electrode 213. As shown in FIG. 5, as viewed in the first direction z, the area of the first gate electrode 213 is smaller than the area of the second electrode 212.

As shown in FIG. 5, the first detection electrode 214 is located on the same side as the second electrode 212 and the first gate electrode 213 in the first direction z. The first detection electrode 214 is located adjacent to the first gate electrode 213 in the third direction y. A voltage equivalent to the voltage applied to the second electrode 212 is applied to the first detection electrode 214. As viewed in the first direction z, the area of the first detection electrode 214 is approximately equivalent to the area of the first gate electrode 213.

As shown in FIGS. 5 and 11, each of the plurality of second semiconductor elements 22 has a third electrode 221, a fourth electrode 222, a second gate electrode 223, and a second detection electrode 224.

As shown in FIG. 11, the third electrode 221 faces the second main surface 122A of the second conductive layer 122. A current corresponding to the electrical power prior to conversion by the second semiconductor element 22 flows through the third electrode 221. That is, the third electrode 221 corresponds to the drain electrode of the second semiconductor element 22. The third electrode 221 is conductively bonded to the second main surface 122A via the conductive bonding layer 29. Consequently, the third electrodes 221 of each of the plurality of second semiconductor elements 22 are electrically connected to the second conductive layer 122.

As shown in FIG. 11, the fourth electrode 222 is located on the side opposite to the side facing the second main surface 122A of the second conductive layer 122 in the first direction z. Therefore, the third electrode 221 and the fourth electrode 222 are located on opposite sides of each other in the first direction z. A current corresponding to the electrical power converted by the second semiconductor element 22 flows through the fourth electrode 222. That is, the fourth electrode 222 corresponds to the source electrode of the second semiconductor element 22.

As shown in FIG. 11, the second gate electrode 223 is positioned on the side opposite to the side facing the second main surface 122A of the second conductive layer 122 in the first direction z. Therefore, the second gate electrode 223 is positioned on the same side as the fourth electrode 222 in the first direction z. A gate voltage for driving the second semiconductor element 22 is applied to the second gate electrode 223. As shown in FIG. 5, as viewed in the first direction z, the area of the second gate electrode 223 is smaller than the area of the fourth electrode 222.

As shown in FIG. 5, the second detection electrode 224 is located on the same side as the fourth electrode 222 and the second gate electrode 223 in the first direction z. The second detection electrode 224 is located on one side of the second gate electrode 223 in the third direction y. A voltage equivalent to the voltage applied to the fourth electrode 222 is applied to the second detection electrode 224. As viewed in the first direction z, the area of the second detection electrode 224 is approximately equivalent to the area of the second gate electrode 223.

As shown in FIGS. 3 and 9, the first power terminal 13 is located on the side opposite to the second conductive layer 122 with respect to the first conductive layer 121 in the second direction x. The first power terminal 13 is conductively bonded to the first conductive layer 121. Consequently, the first power terminal 13 is electrically connected to the first electrode 211 of each of the plurality of first semiconductor elements 21 via the first conductive layer 121. The first power terminal 13 is the P-terminal (positive terminal) to which the DC power to be converted is input. The first power terminal 13 extends in the second direction x from the first conductive layer 121. The first power terminal 13 has a covered portion 131 and an exposed portion 132. As shown in FIG. 9, the covered portion 131 is conductively bonded to the first conductive layer 121 and is covered by the sealing resin 50. The exposed portion 132 extends from the covered portion 131 in the second direction x and is exposed to the outside from the sealing resin 50.

As shown in FIGS. 3 and 8, each of the two second power terminals 14 is located on the same side as the first power terminal 13 with respect to the first conductive layer 121 and the second conductive layer 122 in the second direction x, and is spaced apart from the first conductive layer 121 and the second conductive layer 122. Each of the two second power terminals 14 is electrically connected to the fourth electrode 222 of each of the plurality of second semiconductor elements 22. The two second power terminals 14 are N-terminals (negative terminals) into which DC power to be converted is input. The second power terminals 14 are spaced apart from each other in the third direction y. The first power terminal 13 is located between the two second power terminals 14 in the third direction y. Each of the two second power terminals 14 has a covered portion 141 and an exposed portion 142. As shown in FIG. 8, the covered portion 141 is spaced apart from the first conductive layer 121 and is covered by the sealing resin 50. The exposed portion 142 extends from the covered portion 141 in the second direction x and is exposed to the outside from the sealing resin 50.

As shown in FIGS. 3 and 8, each of the two third power terminals 15 is located on the side opposite to the first conductive layer 121 with respect to the second conductive layer 122 in the second direction x. Each of the two third power terminals 15 is conductively bonded to the second conductive layer 122. Consequently, each of the two third power terminals 15 is electrically connected to the third electrode 221 of each of the plurality of second semiconductor elements 22 via the second conductive layer 122. AC power converted by the plurality of first semiconductor elements 21 and the plurality of second semiconductor elements 22 is output from each of the two third power terminals 15. In the semiconductor device A10, the two third power terminals 15 are spaced apart from each other in the third direction y. Each of the two third power terminals 15 has a covered portion 151 and an exposed portion 152. As shown in FIG. 8, the covered portion 151 is conductively bonded to the second conductive layer 122 and is covered by the sealing resin 50. The exposed portion 152 extends from the covered portion 151 in the second direction x and is exposed to the outside from the sealing resin 50.

As shown in FIG. 10, the first wiring 61 is bonded to the first main surface 121A of the first conductive layer 121. The first wiring 61 is located on the side opposite to the plurality of second semiconductor elements 22 with respect to the plurality of first semiconductor elements 21 in the second direction x. The first wiring 61 is electrically connected to the plurality of first semiconductor elements 21 and the first conductive layer 121. As shown in FIGS. 5 and 10, the first wiring 61 has a first mounting layer 611, a first metal layer 612, two first gate wiring layers 613, a first detection wiring layer 614, a first temperature detection wiring layer 615, and a second detection wiring layer 616.

As shown in FIG. 5, the first mounting layer 611 mounts the two first gate wiring layers 613, the first detection wiring layer 614, the two first temperature detection wiring layers 615, and the second detection wiring layer 616. The first mounting layer 611 is an insulator. The first mounting layer 611 is, for example, made of ceramics. In addition, the first mounting layer 611 may be made of an insulating resin sheet.

As shown in FIG. 10, the first metal layer 612 is located on the side facing the first main surface 121A of the first conductive layer 121 with respect to the first mounting layer 611 in the first direction z. The first metal layer 612 is bonded to the first mounting layer 611. The first metal layer 612 includes copper. The first metal layer 612 is bonded to the first main surface 121A via a second bonding layer 68. The second bonding layer 68 is, for example, solder.

As shown in FIGS. 5 and 10, the two first gate wiring layers 613 are located on the side opposite to the first metal layer 612 with respect to the first mounting layer 611. The two first gate wiring layers 613 are bonded to the first mounting layer 611. A plurality of first wires 41 are conductively bonded to one first gate wiring layer 613 of the two first gate wiring layers 613. The plurality of first wires 41 are individually conductively bonded to the first gate electrode 213 of each of the plurality of first semiconductor elements 21. Furthermore, a plurality of sixth wires 46 are conductively bonded to each of the two first gate wiring layers 613. As a result, each of the two first gate wiring layers 613 is electrically connected to the first gate electrode 213 of each of the plurality of first semiconductor elements 21.

As shown in FIGS. 5 and 10, the first detection wiring layer 614 is located on the side opposite to the first metal layer 612 with respect to the first mounting layer 611. The first detection wiring layer 614 is bonded to the first mounting layer 611. A plurality of second wires 42 are conductively bonded to the first detection wiring layer 614. Furthermore, the plurality of second wires 42 are individually conductively bonded to the first detection electrode 214 of each of the plurality of first semiconductor elements 21. Consequently, the first detection wiring layer 614 is electrically connected to the first detection electrode 214 of each of the plurality of first semiconductor elements 21.

As shown in FIG. 5, the two first temperature detection wiring layers 615 are located on the side opposite to the first metal layer 612 with respect to the first mounting layer 611. The two first temperature detection wiring layers 615 are bonded to the first mounting layer 611. The two first temperature detection wiring layers 615 are adjacent to each other in the third direction y.

As shown in FIGS. 5 and 10, the second detection wiring layer 616 is located on the side opposite to the first metal layer 612 with respect to the first mounting layer 611. The second detection wiring layer 616 is bonded to the first mounting layer 611. The third wire 43 is conductively bonded to the second detection wiring layer 616. Furthermore, the third wire 43 is conductively bonded to the first main surface 121A of the first conductive layer 121. As a result, the second detection wiring layer 616 is electrically connected to the first conductive layer 121.

As shown in FIG. 11, the second wiring 62 is bonded to the second main surface 122A of the second conductive layer 122. The second wiring 62 is located on the side opposite to the plurality of first semiconductor elements 21 with respect to the plurality of second semiconductor elements 22 in the second direction x. The second wiring 62 is electrically connected to the plurality of second semiconductor elements 22 and the second conductive layer 122. As shown in FIGS. 5 and 11, the second wiring 62 has a second mounting layer 621, a second metal layer 622, two second gate wiring layers 623, a third detection wiring layer 624, two second temperature detection wiring layers 625, and a fourth detection wiring layer 626.

As shown in FIG. 5, the second mounting layer 621 mounts the two second gate wiring layers 623, the third detection wiring layer 624, the two second temperature detection wiring layers 625, and the fourth detection wiring layer 626. The second mounting layer 621 is an insulator. The second mounting layer 621 is made of, for example, ceramic. Alternatively, the second mounting layer 621 may be made of an insulating resin sheet.

As shown in FIG. 11, the second metal layer 622 is located on the side facing the second main surface 122A of the second conductive layer 122 with respect to the second mounting layer 621 in the first direction z. The second metal layer 622 is bonded to the second mounting layer 621. The second metal layer 622 contains copper. The second metal layer 622 is bonded to the second main surface 122A via the second bonding layer 68.

As shown in FIGS. 5 and 11, the two second gate wiring layers 623 are located on the side opposite to the second metal layer 622 with respect to the second mounting layer 621. The two second gate wiring layers 623 are bonded to the second mounting layer 621. A plurality of fourth wires 44 are conductively bonded to one of the second gate wiring layers 623. The plurality of fourth wires 44 are individually conductively bonded to the second gate electrode 223 of each of the plurality of second semiconductor elements 22. Furthermore, a plurality of seventh wires 47 are conductively bonded to each of the two second gate wiring layers 623. As a result, each of the two second gate wiring layers 623 is electrically connected to the second gate electrode 223 of each of the plurality of second semiconductor elements 22.

As shown in FIGS. 5 and 11, the third detection wiring layer 624 is located on the side opposite to the second metal layer 622 with respect to the second mounting layer 621. The third detection wiring layer 624 is bonded to the second mounting layer 621. A plurality of fifth wires 45 are conductively bonded to the third detection wiring layer 624. Furthermore, the plurality of fifth wires 45 are individually conductively bonded to the second detection electrode 224 of each of the plurality of second semiconductor elements 22. Consequently, the third detection wiring layer 624 is electrically connected to the second detection electrode 224 of each of the plurality of second semiconductor elements 22.

As shown in FIGS. 5 and 11, the two second temperature detection wiring layers 625 are located on the side opposite to the second metal layer 622 with respect to the second mounting layer 621. The two second temperature detection wiring layers 625 are bonded to the second mounting layer 621. The two second temperature detection wiring layers 625 are adjacent to each other in the third direction y.

As shown in FIGS. 5 and 11, the fourth detection wiring layer 626 is located on the side opposite to the second metal layer 622 with respect to the second mounting layer 621. The fourth detection wiring layer 626 is bonded to the second mounting layer 621.

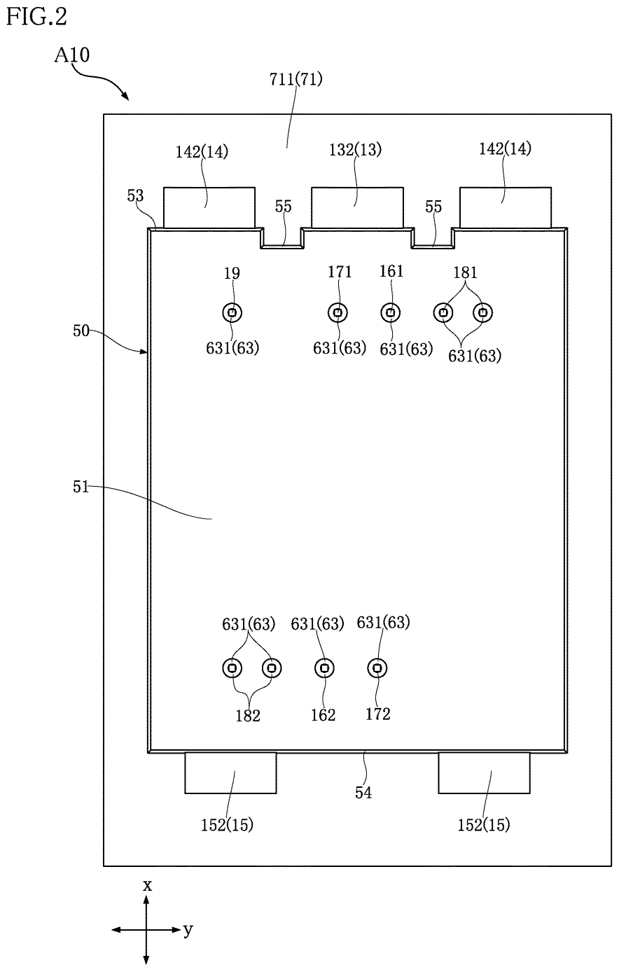

As shown in FIGS. 10 and 11, each of the plurality of sleeves 63 is conductively bonded to either the first wiring 61 or the second wiring 62 via the third bonding layer 69. The third bonding layer 69 is, for example, solder. The plurality of sleeves 63 are made of a conductive material such as metal. Each of the plurality of sleeves 63 is tubular and extends in the first direction z. As shown in FIGS. 2 and 9, each of the plurality of sleeves 63 has an end face 631 that faces the same side as the first main surface 121A of the first conductive layer 121 in the first direction z. The end face 631 is exposed from the top surface 51 of the sealing resin 50, which will be described later, to the outside.

As shown in FIG. 4, one of the two thermistors 23 is conductively bonded to the two first temperature detection wiring layers 615 of the first wiring 61. As shown in FIG. 4, the other one of the two thermistors 23 is conductively bonded to the two second temperature detection wiring layers 625 of the second wiring 62. The two thermistors 23 are used as temperature detection sensors for the semiconductor device A10.

The first signal terminal 161, the second signal terminal 162, the third signal terminal 171, the fourth signal terminal 172, the two fifth signal terminals 181, the two sixth signal terminals 182, and the seventh signal terminal 19 consist of metal pins extending in the first direction z, as shown in FIG. 1. These terminals protrude from the top surface 51 of the sealing resin 50, which will be described later. Furthermore, these terminals are individually press-fitted into the plurality of sleeves 63. As a result, each of these terminals is supported by one of the plurality of sleeves 63 and is electrically connected to either the first wiring 61 or the second wiring 62.

As shown in FIGS. 5 and 10, the first signal terminal 161 is press-fitted into the sleeve 63 which is conductively bonded to one of the two first gate wiring layers 613 of the first wiring 61, from among the plurality of sleeves 63. As a result, the first signal terminal 161 is electrically connected to the first gate electrode 213 of each of the plurality of first semiconductor elements 21 via the two first gate wiring layers 613. A gate voltage for driving the plurality of first semiconductor elements 21 is applied to the first signal terminal 161.

As shown in FIGS. 5 and 11, the second signal terminal 162 is press-fitted into the sleeve 63 which is conductively bonded to one of the two second gate wiring layers 623 of the second wiring 62, from among the plurality of sleeves 63. Consequently, the second signal terminal 162 is electrically connected to the second gate electrode 223 of each of the plurality of second semiconductor elements 22 via the two second gate wiring layers 623. A gate voltage for driving the plurality of second semiconductor elements 22 is applied to the second signal terminal 162.

As shown in FIG. 2, the third signal terminal 171 is located adjacent to the first signal terminal 161 in the third direction y. As shown in FIG. 5, the third signal terminal 171 is press-fitted into the sleeve 63 which is conductively bonded to the first detection wiring layer 614 of the first wiring 61, from among the plurality of sleeves 63. Consequently, the third signal terminal 171 is electrically connected to the first detection electrode 214 of each of the plurality of first semiconductor elements 21 via the first detection wiring layer 614. A voltage equivalent to the voltage applied to the first detection electrode 214 of each of the plurality of first semiconductor elements 21 is applied to the third signal terminal 171.

As shown in FIG. 2, the fourth signal terminal 172 is located adjacent to the second signal terminal 162 in the third direction y. As shown in FIG. 5, the fourth signal terminal 172 is press-fitted into the sleeve 63 which is conductively bonded to the third detection wiring layer 624 of the second wiring 62, from among the plurality of sleeves 63. Consequently, the fourth signal terminal 172 is electrically connected to the second detection electrode 224 of each of the plurality of second semiconductor elements 22 via the third detection wiring layer 624. A voltage equivalent to the voltage applied to the second detection electrode 224 of each of the plurality of second semiconductor elements 22 is applied to the fourth signal terminal 172.

As shown in FIG. 2, the two fifth signal terminals 181 are located on the side opposite to the third signal terminal 171 with respect to the first signal terminal 161 in the third direction y. The two fifth signal terminals 181 are adjacent to each other in the third direction y. As shown in FIG. 5, the two fifth signal terminals 181 are individually press-fitted into the two sleeves 63 which are individually conductively bonded to the two first temperature detection wiring layers 615 of the first wiring 61, from among the plurality of sleeves 63. As a result, the two fifth signal terminals 181 are electrically connected to the thermistor 23 which is conductively bonded to the two first temperature detection wiring layers 615, from among the two thermistors 23.

As shown in FIG. 2, the two sixth signal terminals 182 are located on the side opposite to the fourth signal terminal 172 with respect to the second signal terminal 162 in the third direction y. The two sixth signal terminals 182 are adjacent to each other in the third direction y. As shown in FIG. 5, the two sixth signal terminals 182 are individually press-fitted into the two sleeves 63 which are individually conductively bonded to the two second temperature detection wiring layers 625 of the second wiring 62, from among the plurality of sleeves 63. As a result, the two sixth signal terminals 182 are electrically connected to the thermistor 23 which is conductively bonded to the two second temperature detection wiring layers 625, from among the two thermistors 23.

As shown in FIG. 2, the seventh signal terminal 19 is located on the side opposite to the first signal terminal 161 with respect to the third signal terminal 171 in the third direction y. As shown in FIG. 5, the seventh signal terminal 19 is press-fitted into the sleeve 63 which is conductively bonded to the second detection wiring layer 616 of the first wiring 61, from among the plurality of sleeves 63. Consequently, the seventh signal terminal 19 is electrically connected to the first conductive layer 121 via the second detection wiring layer 616. A voltage corresponding to the DC power input to the first power terminal 13 and the two second power terminals 14 is applied to the seventh signal terminal 19.

As shown in FIGS. 5 and 10, the first conductive connection member 31 is conductively bonded to the second electrodes 212 of the plurality of first semiconductor elements 21 and to the second main surface 122A of the second conductive layer 122. Consequently, the second electrodes 212 of the plurality of first semiconductor elements 21 are electrically connected to the second conductive layer 122. The first conductive connection member 31 contains copper. The first conductive connection member 31 is a metal clip. As shown in FIG. 5, the first conductive connection member 31 has a first main portion 311, a plurality of first bonding portions 312, a plurality of first connecting portions 313, a plurality of second bonding portions 314, and a plurality of second connecting portions 315.

The first main portion 311 constitutes the main body of the first conductive connection member 31. As shown in FIG. 5, the first main portion 311 extends in the third direction y. As shown in FIG. 9, the first main portion 311 spans the space between the first conductive layer 121 and the second conductive layer 122.

As shown in FIG. 10, the plurality of first bonding portions 312 are individually bonded to the second electrodes 212 of the plurality of first semiconductor elements 21. Each of the plurality of first bonding portions 312 faces the second electrode 212 of one of the plurality of first semiconductor elements 21.

As shown in FIG. 5, the plurality of first connecting portions 313 are connected to the first main portion 311 and the plurality of first bonding portions 312. The plurality of first connecting portions 313 are spaced apart from one another in the third direction y. As shown in FIG. 9, as viewed in the third direction y, the plurality of first connecting portions 313 are inclined away from the first main surface 121A of the first conductive layer 121 as they extend from the plurality of first bonding portions 312 toward the first main portion 311.

As shown in FIGS. 5 and 9, the plurality of second bonding portions 314 are bonded to the second main surface 122A of the second conductive layer 122. The plurality of second bonding portions 314 face the second main surface 122A. The plurality of second bonding portions 314 extend in the third direction y.

As shown in FIGS. 5 and 9, the plurality of second connecting portions 315 are connected to the first main portion 311 and the plurality of second bonding portions 314. As viewed in the third direction y, the plurality of second connecting portions 315 are inclined away from the second main surface 122A of the second conductive layer 122 as they extend from the plurality of second bonding portions 314 toward the first main portion 311.

As shown in FIGS. 9, 10, and 13, a conductive bonding layer 29 is positioned between the second electrode 212 of each of the plurality of first semiconductor elements 21 and each of the plurality of first bonding portions 312. This conductive bonding layer 29 individually conductively bonds each of the plurality of first bonding portions 312 to the second electrode 212 of each of the plurality of first semiconductor elements 21. As shown in FIG. 9, the conductive bonding layer 29 is positioned between the second main surface 122A of the second conductive layer 122 and the second bonding portion 314. This conductive bonding layer 29 conductively bonds the second main surface 122A and the second bonding portion 314.

As shown in FIGS. 4 and 11, the second conductive connection member 32 is conductively bonded to the fourth electrodes 222 of the plurality of second semiconductor elements 22 and to the covered portion 141 of the second power terminal 14. Consequently, the fourth electrodes 222 of the plurality of second semiconductor elements 22 are electrically connected to the second power terminal 14. The second conductive connection member 32 contains copper. The second conductive connection member 32 is a metal clip. As shown in FIG. 4, the second conductive connection member 32 has two second main portions 321, a plurality of third bonding portions 322, a plurality of third connecting portions 323, two fourth bonding portions 324, two fourth connecting portions 325, a plurality of intermediate portions 326, and a plurality of crossbeam portions 327.

As shown in FIG. 4, the two second main portions 321 are spaced apart from each other in the third direction y. The two second main portions 321 extend in the second direction x. As shown in FIG. 8, the two second main portions 321 are arranged parallel to the first main surface 121A of the first conductive layer 121 and the second main surface 122A of the second conductive layer 122. The two second main portions 321 are located farther from the first main surface 121A and the second main surface 122A than the first main portion 311 of the first conductive connection member 31.

As shown in FIG. 4, the plurality of intermediate portions 326 are spaced apart from one another in the third direction y and are located between the two second main portions 321 in the third direction y. The plurality of intermediate portions 326 extend in the second direction x. The dimension in the second direction x of each of the plurality of intermediate portions 326 is smaller than the dimension in the second direction x of each of the two second main portions 321.

As shown in FIG. 11, the plurality of third bonding portions 322 are individually bonded t the fourth electrodes 222 of the plurality of second semiconductor elements 22. Each of the plurality of third bonding portions 322 faces the fourth electrode 222 of one of the plurality of second semiconductor elements 22.

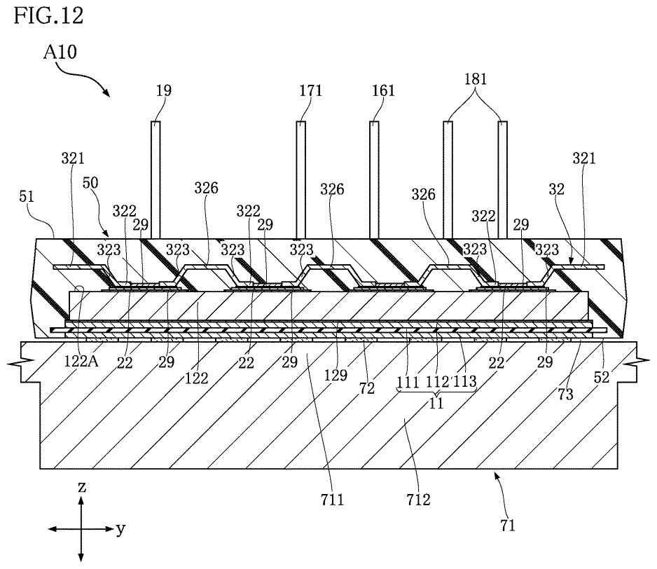

As shown in FIGS. 4 and 12, the plurality of third connecting portions 323 are connected to both sides in the third direction y of the plurality of third bonding portions 322. Furthermore, the plurality of third connecting portions 323 are connected to either of the two second main portions 321 and the plurality of intermediate portions 326. As viewed in the second direction x, each of the plurality of third connecting portions 323 is inclined away from the second main surface 122A of the second conductive layer 122 as it extends from one of the plurality of third bonding portions 322 toward one of the two second main portions 321 and the plurality of intermediate portions 326.

As shown in FIGS. 4 and 8, the two fourth bonding portions 324 are bonded to the covered portion 141 of the second power terminal 14. The two fourth bonding portions 324 face the covered portion 141.

As shown in FIGS. 4 and 8, the two fourth connecting portions 325 are connected to the two second main portions 321 and the two fourth bonding portions 324. As viewed in the third direction y, the two fourth connecting portions 325 are inclined away from the first main surface 121A of the first conductive layer 121 as they extend from the two fourth bonding portions 324 toward the two second main portions 321.

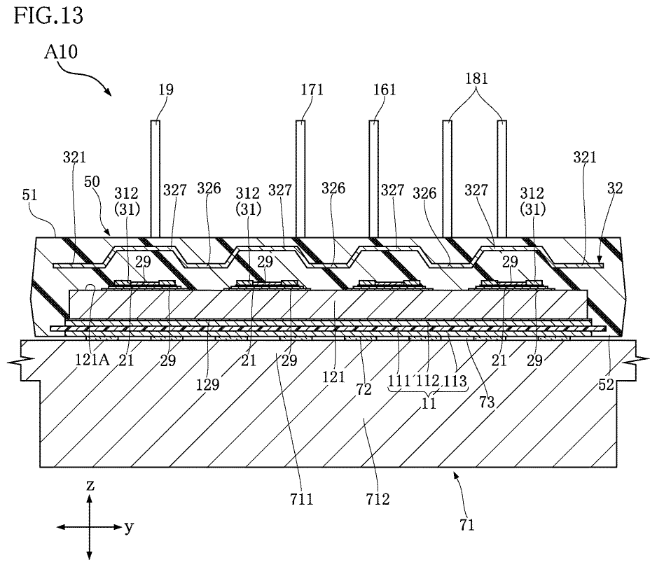

As shown in FIGS. 4 and 13, the plurality of crossbeam portions 327 are arranged along the third direction y. As viewed in the first direction z, the plurality of crossbeam portions 327 include regions that individually overlap with the plurality of first bonding portions 312 of the first conductive connection member 31. Both sides in the third direction y of the crossbeam portions 327 located at the center in the third direction y among the plurality of crossbeam portions 327 are connected to the plurality of intermediate portions 326. Both sides in the third direction y of the remaining two crossbeam portions 327 among the plurality of crossbeam portions 327 are connected to one of the two second main portions 321 and one of the plurality of intermediate portions 326. As viewed in the second direction x, the plurality of crossbeam portions 327 are convex toward the side to which the first main surface 121A of the first conductive layer 121 faces in the first direction z.

As shown in FIGS. 9, 11, and 12, the conductive bonding layer 29 is located between the fourth electrode 222 of each of the plurality of second semiconductor elements 22 and each of the plurality of third bonding portions 322. This conductive bonding layer 29 individually conductively bonds each of the plurality of third bonding portions 322 to the fourth electrode 222 of each of the plurality of second semiconductor elements 22. As shown in FIG. 8, the conductive bonding layer 29 is located between the covered portion 141 of each of the two second power terminals 14 and the two fourth bonding portions 324. This conductive bonding layer 29 individually conductively bonds the covered portions 141 of each of the two second power terminals 14 to the two fourth bonding portions 324.

As shown in FIGS. 8, 9, 12, and 13, the sealing resin 50 covers the first conductive layer 121, the second conductive layer 122, the plurality of first semiconductor elements 21, the plurality of second semiconductor elements 22, the first conductive connection member 31, and the second conductive connection member 32. Furthermore, the sealing resin 50 covers a portion of each of the base material 11, the first power terminal 13, the third power terminal 15, and the second power terminal 14. The sealing resin 50 has electrical insulating properties. The sealing resin 50 is composed of a material containing, for example, black epoxy resin. As shown in FIGS. 2, 6 to 9, the sealing resin 50 has a top surface 51, a bottom surface 52, a first side surface 53, a second side surface 54, and two recesses 55.

As shown in FIGS. 8 and 9, the top surface 51 faces the same side as the first main surface 121A of the first conductive layer 121 in the first direction z. As shown in FIGS. 8 and 9, the bottom surface 52 faces the side opposite to the top surface 51 in the first direction z. As shown in FIG. 7, the heat dissipation layer 113 of the base material 11 is exposed from the bottom surface 52.

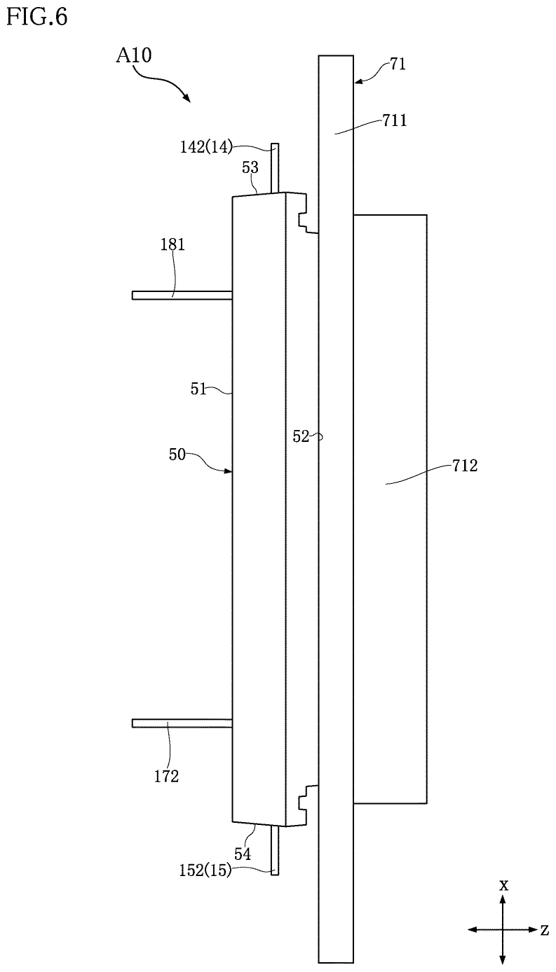

As shown in FIGS. 2 and 6, the first side surface 53 and the second side surface 54 are spaced apart from each other in the second direction x. The first side surface 53 and the second side surface 54 face opposite sides of each other in the second direction x. The exposed portion 132 of the first power terminal 13 and the exposed portion 142 of each of the two second power terminals 14 are exposed from the first side surface 53 to the outside. The exposed portion 152 of each of the two third power terminals 15 is exposed from the second side surface 54 to the outside.

As shown in FIGS. 2 and 7, the two recesses 55 are recessed from the first side surface 53 toward the second direction x. The two recesses 55 extend from the top surface 51 to the bottom surface 52 in the first direction z. The two recesses 55 are located on both sides of the first power terminal 13 in the third direction y.

The heat dissipation member 71 is used to cool the semiconductor device A10. The heat dissipation member 71 contains metal. The heat dissipation member 71 is made of a material containing, for example, aluminum (Al).

As shown in FIGS. 6 and 7, the heat dissipation member 71 has a base portion 711 and a heat dissipation portion 712. The base portion 711 is flat. The base portion 711 faces the heat dissipation layer 113 of the base material 11 in the first direction z. As shown in FIG. 2, as viewed in the first direction z, the sealing resin 50 is located inward of the periphery of the base portion 711. The heat dissipation portion 712 is connected to the base portion 711. The heat dissipation portion 712 is located on the side opposite to the base material 11 with respect to the base portion 711 in the first direction z. The heat dissipation portion 712 protrudes from the base portion 711. In the semiconductor device A10, the heat dissipation portion 712 is cuboid in shape. Alternatively, the heat dissipation portion 712 may be composed of a plurality of fins arranged in a direction orthogonal to the first direction z. As shown in FIG. 6, as viewed in the first direction z, the heat dissipation portion 712 is located inward of the periphery of the sealing resin 50.

As shown in FIGS. 8 to 13, the bonding layer 72 bonds the base portion 711 of the heat dissipation member 71 to the heat dissipation layer 113 of the base material 11. The bonding layer 72 includes a sintered body of metal particles. The metal particles contain silver. Alternatively, the metal particles may contain copper.

As shown in FIGS. 10, 11, and 14, the bonding layer 72 is provided with a void portion 73 that penetrates through it in the first direction z. The void portion 73 is exposed to the outside of the semiconductor device A10. As shown in FIG. 14, as viewed in the first direction z, the heat dissipation layer 113 of the base material 11 has a first edge 113A and a second edge 113B. The first edge 113A extends in the second direction x. The second edge 113B extends in a direction perpendicular to the first direction z and different from the second direction x. As viewed in the first direction z, the first edge 113A or its extended line and the second edge 113B or its extended line intersect at a first intersection point P1. As viewed in the first direction z, the void portion 73 includes a portion located between the first intersection point P1 and the bonding layer 72.

As shown in FIG. 14, the bonding layer 72 includes a first bonding portion 721, a second bonding portion 722, and a third bonding portion 723, which are spaced apart from one another in a direction orthogonal to the first direction z. Thus, the bonding layer 72 includes a plurality of spaced-apart regions. Among these spaced-apart regions, the void portion 73 is provided between any two adjacent regions. In addition, the bonding layer 72 may be configured to be a single region provided that a void portion 73 is formed. The first bonding portion 721 and the second bonding portion 722 are spaced apart from each other in the second direction x and are adjacent to each other. The third bonding portion 723 is spaced apart from the first bonding portion 721 and the second bonding portion 722 in a direction orthogonal to the first direction z. As viewed in the first direction z, the areas of the first bonding portion 721, the second bonding portion 722, and the third bonding portion 723 are equivalent to one another. As viewed in the first direction z, the first bonding portion 721, the second bonding portion 722, and the third bonding portion 723 are each circular in shape.

As shown in FIG. 14, the third bonding portion 723 is located adjacent to the first bonding portion 721 and the second bonding portion 722 in a direction perpendicular to the first direction z. As viewed in the first direction z, a virtual line passing through the center C0 of the third bonding portion 723 and extending in the third direction y coincides with the void portion 73 located between the first bonding portion 721 and the second bonding portion 722.

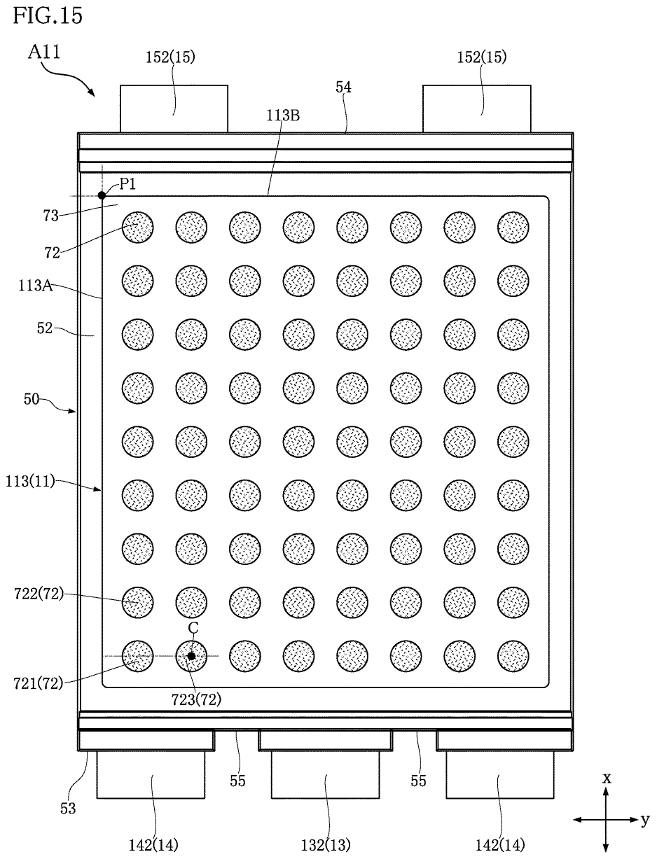

Next, with reference to FIG. 15, the semiconductor device A11 according to a first variation of the first embodiment of the present disclosure will be described. FIG. 15 corresponds to FIG. 14, which shows the semiconductor device A10. In the semiconductor device A11, the configuration of the bonding layer 72 differs from that of the semiconductor device A10.

As shown in FIG. 15, the third bonding portion 723 is located adjacent to the first bonding portion 721 in the third direction y. As viewed in the first direction z, a virtual line passing through the center C0 of the third bonding portion 723 and extending in the third direction y overlaps with the first bonding portion 721. In the semiconductor device A11, the plurality of regions constituting the bonding layer 72 are arranged in a lattice pattern.

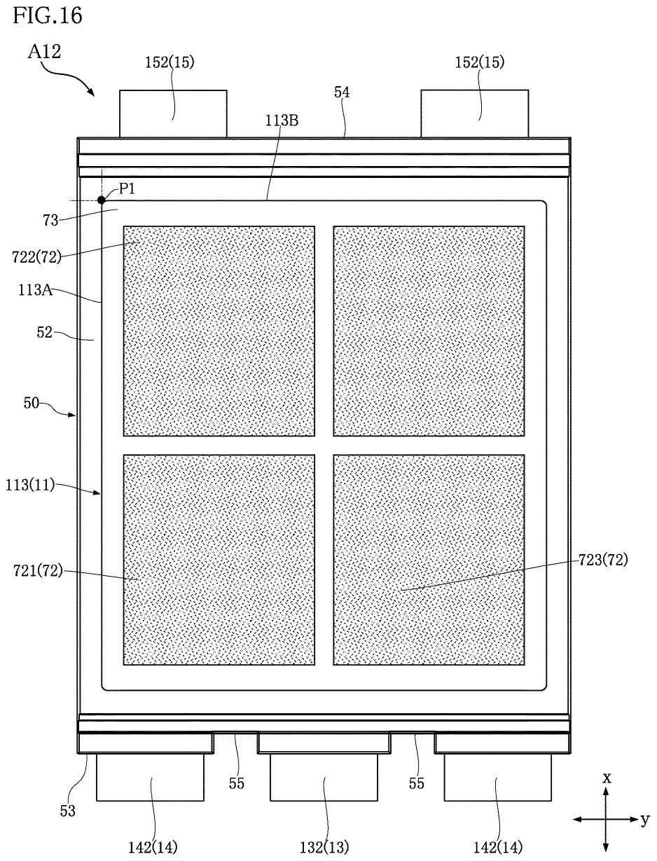

Next, with reference to FIG. 16, the semiconductor device A12 according to a second variation of the first embodiment of the present disclosure will be described. FIG. 16 corresponds to FIG. 14, which shows the semiconductor device A10. In the semiconductor device A12, the configuration of the bonding layer 72 differs from that of the semiconductor device A10.

As shown in FIG. 16, as viewed in the first direction z, the first bonding portion 721, the second bonding portion 722, and the third bonding portion 723 are each rectangular in shape. The third bonding portion 723 is located adjacent to the first bonding portion 721 in the third direction y. As viewed in the first direction z, the area of each of the first bonding portion 721, the second bonding portion 722, and the third bonding portion 723 is larger than the area of each of the first bonding portion 721, the second bonding portion 722, and the third bonding portion 723 in the semiconductor device A10.

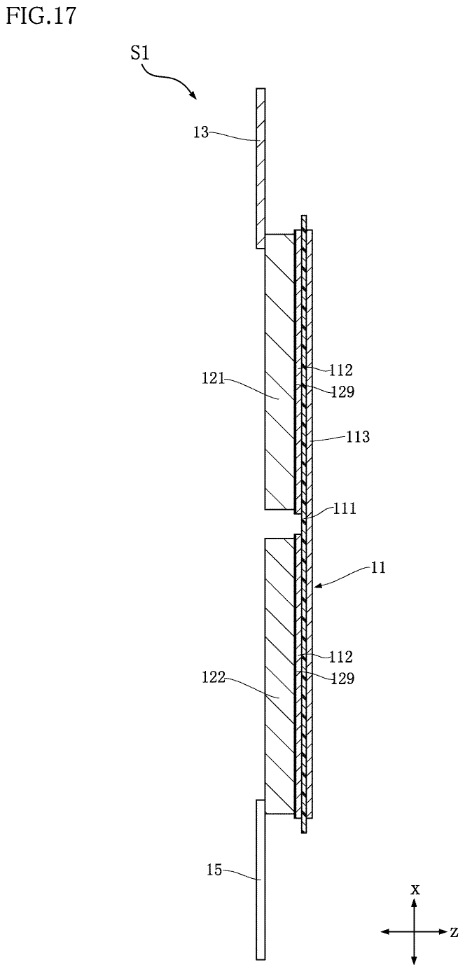

Next, with reference to FIGS. 17 to 20, an example of a method for manufacturing the semiconductor device A10 will be described. FIGS. 17 to 20 correspond to FIG. 9, which illustrates the semiconductor device A10.

First, the first step S1 shown in FIG. 17 is performed. In the first step S1, the first conductive layer 121 and the second conductive layer 122 are bonded to the base material 11, which includes the heat dissipation layer 113, such that they are positioned on the side of the base material 11 opposite to the heat dissipation layer 113 in the first direction z. The first conductive layer 121 and the second conductive layer 122 are individually bonded to the two support layers 112 of the base material 11 via the first bonding layer 129. Furthermore, in the first step S1, the first power terminal 13 is conductively bonded to the first conductive layer 121 by laser welding. Concurrently, the two third power terminals 15 are conductively bonded to the second conductive layer 122 by laser welding.

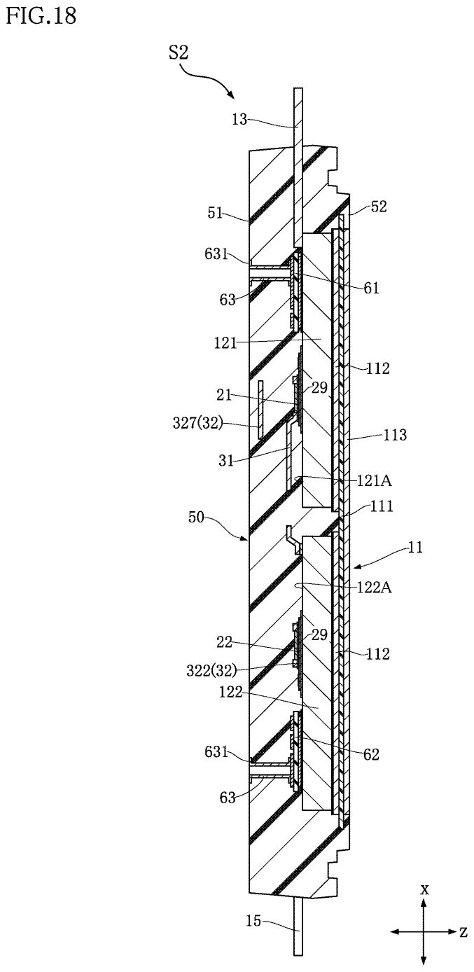

Next, the second step S2 shown in FIG. 18 is performed. In the second step S2, the plurality of first semiconductor elements 21 are conductively bonded to the first conductive layer 121 via the conductive bonding layer 29. Concurrently, the plurality of second semiconductor elements 22 are conductively bonded to the second conductive layer 122 via the conductive bonding layer 29. Subsequently, the first conductive connection member 31 is conductively bonded to the plurality of first semiconductor elements 21 and the second conductive layer 122. Thereafter, after positioning two second power terminals 14, the second conductive connection member 32 is conductively bonded to the plurality of second semiconductor elements 22 and the two second power terminals 14. Thereafter, the first wiring 61 is bonded to the first conductive layer 121. At the same time, the second wiring 62 is bonded to the second conductive layer 122. Furthermore, the sealing resin 50 is formed to cover the first conductive layer 121, the second conductive layer 122, the plurality of first semiconductor elements 21, the plurality of second semiconductor elements 22, the first conductive connection member 31, and the second conductive connection member 32. The sealing resin 50 is formed by transfer molding. When forming the sealing resin 50, the heat dissipation layer 113 of the base material 11 and the end faces 631 of each of the plurality of sleeves 63 are exposed from the sealing resin 50.

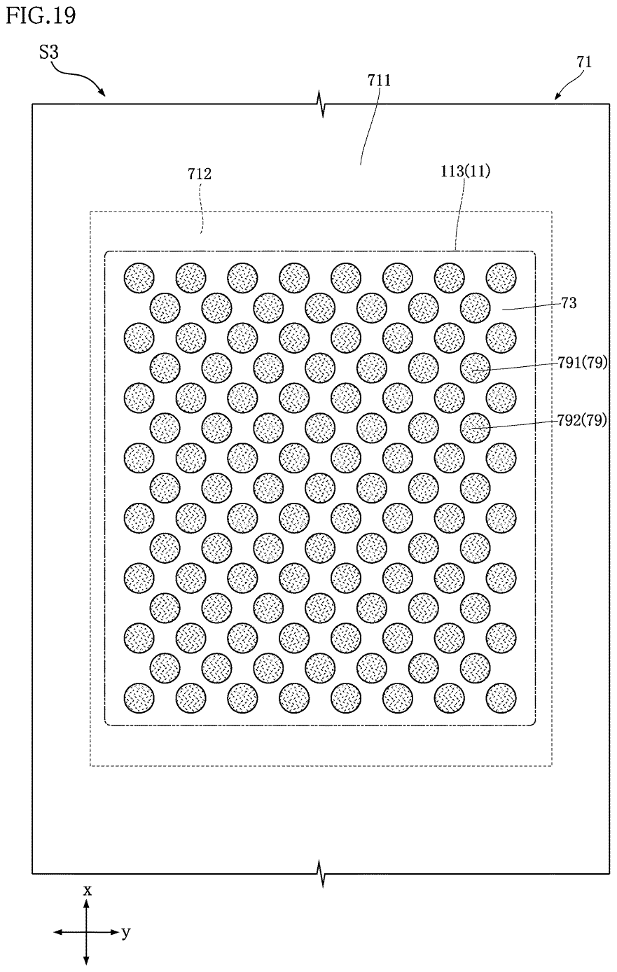

Next, the third step S3 shown in FIG. 19 is performed. In the third step S3, bonding material 79 is placed on one side in the first direction z of either the base portion 711 of the heat dissipation member 71 or the heat dissipation layer 113 of the base material 11. In this process, bonding material 79 is placed on one side in the first direction z of the base portion 711. The bonding material 79 is a paste containing metal particles and solvent. The metal particles contain silver. The bonding material 79 is applied to the base portion 711 using a dispenser or screen printing. In the third step S3, the void portion 73 penetrating the bonding material 79 in the first direction z is formed in the bonding material 79. In the third step S3, the bonding material 79 is arranged to include a first portion 791 and a second portion 792 that are spaced apart from each other in a direction orthogonal to the first direction z. Furthermore, in the third step S3, the void portion 73 is formed so that it is exposed to the outside in a direction orthogonal to the first direction z. After placing the bonding material 79 on the base portion 711, the solvent contained in the bonding material 79 is removed by drying the bonding material 79.

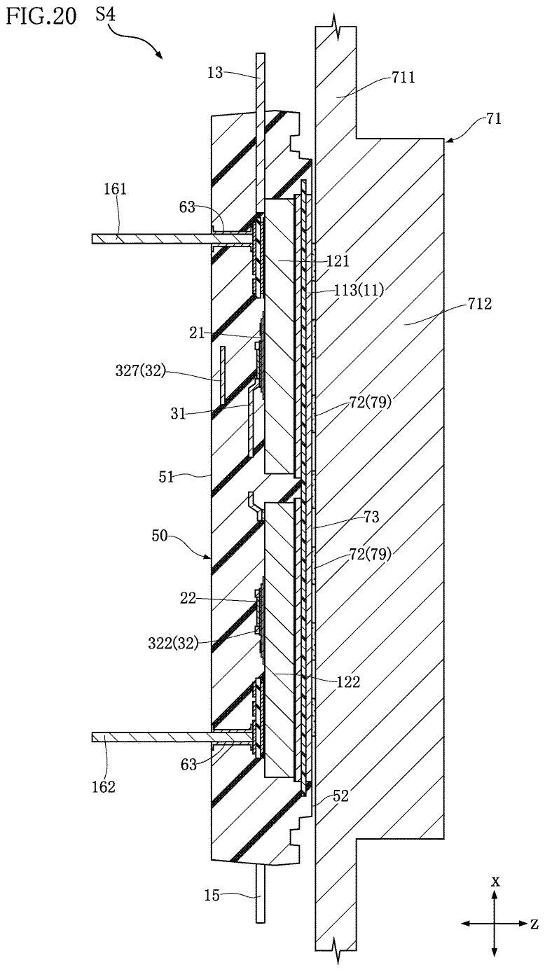

Next, the fourth step S4 shown in FIG. 20 is performed. In the fourth step S4, the bonding material 79 is sintered to bond the heat dissipation member 71 to the heat dissipation layer 113 of the base material 11. The bonding material 79 sintered in the fourth step S4 becomes the bonding layer 72 of the semiconductor device A10.

Finally, the first signal terminal 161, the second signal terminal 162, the third signal terminal 171, the fourth signal terminal 172, the two fifth signal terminals 181, the two sixth signal terminals 182, and the seventh signal terminal 19 are each individually press-fitted into the plurality of sleeves 63. By undergoing the above steps, the semiconductor device A10 is obtained.

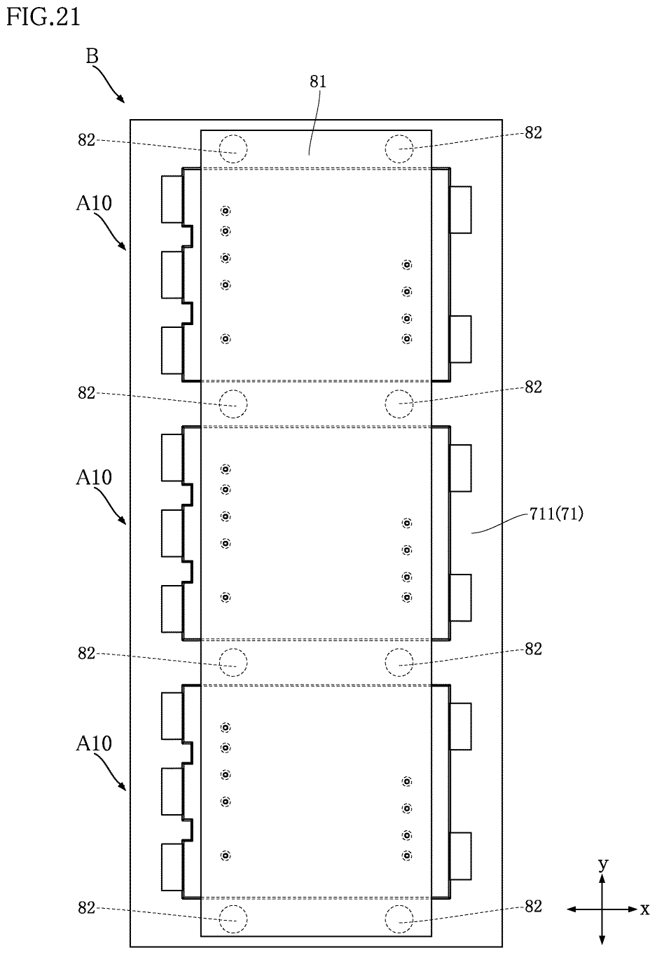

Next, with reference to FIGS. 21 to 27, the inverter device B equipped with the semiconductor device A10 will be described. The inverter device B includes three semiconductor devices A10, a wiring substrate 81, and a plurality of support members 82. The inverter device B is used to drive the motor 89 described below.

First, with reference to FIGS. 21 to 24, the configuration of inverter device B will be described. As shown in FIG. 21, the three semiconductor devices A10 are arranged along the third direction y on the base portion 711 of the heat dissipation member 71. In the inverter device B, the heat dissipation members 71 of the respective three semiconductor devices A10 are integrated. The heat dissipation layers 113 of the respective three semiconductor devices A10 are bonded to the base portion 711 via bonding layers 72.

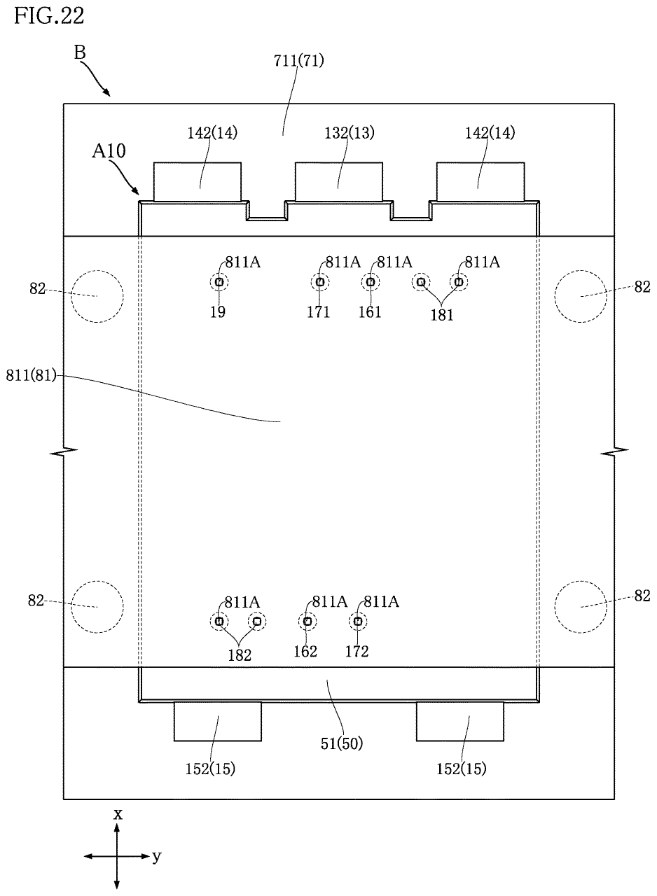

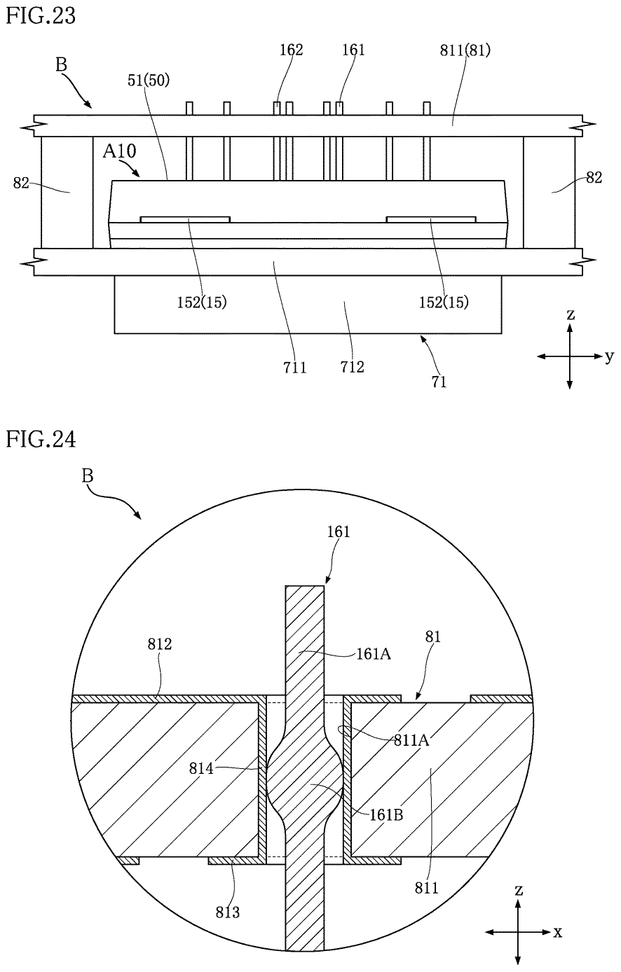

The wiring substrate 81 is individually electrically connected to the first signal terminal 161, the second signal terminal 162, the third signal terminal 171, the fourth signal terminal 172, the two fifth signal terminals 181, the two sixth signal terminals 182, and the seventh signal terminal 19 of each of the three semiconductor devices A10. As shown in FIGS. 22 and 23, the wiring substrate 81 faces the top surface 51 of the sealing resin 50 of each of the three semiconductor devices A10.

As shown in FIG. 24, the wiring substrate 81 includes a substrate 811, a main-side wiring 812, a back-side wiring 813, and an internal wiring 814. The substrate 811 is provided with a plurality of through-holes 811A that penetrate in the first direction z. The main-side wiring 812 is provided on the side opposite to the sealing resin 50 of each of the three semiconductor devices A10, with respect to the substrate 811 in the first direction z. The back-side wiring 813 is provided on the side opposite to the main-side wiring 812, with respect to the substrate 811. The internal wiring 814 is provided in the plurality of through-holes 811A. The internal wiring 814 is connected to the main-side wiring 812 and the back-side wiring 813. The main-side wiring 812 forms a conductive path between the internal wiring 814 and the control circuit 83 and the plurality of drive circuits 84 provided on the wiring substrate 81. Details of the control circuit 83 and the plurality of drive circuits 84 will be described later.

As shown in FIG. 24, the first signal terminal 161 of each of the three semiconductor devices A10 has a base portion 161A and a bulging portion 161B. One side of the base portion 161A in the first direction z is press-fitted into one of the plurality of sleeves 63 of each of the three semiconductor devices A10. The bulging portion 161B is provided on the other side of the base portion 161A in the first direction z. The bulging portion 161B bulges in a direction perpendicular to the first direction z.

As shown in FIG. 22, the first signal terminal 161 of each of the three semiconductor devices A10 is press-fitted into one of the plurality of through-holes 811A. Consequently, as shown in FIG. 24, the internal wiring 814 located in one of the plurality of through-holes 811A is crimped to the bulging portion 161B of the first signal terminal 161. As a result, the first signal terminal 161 is electrically connected to the wiring substrate 81. The second signal terminal 162, the third signal terminal 171, the fourth signal terminal 172, the two fifth signal terminals 181, the two sixth signal terminals 182, and the seventh signal terminal 19 of each of the three semiconductor devices A10 also have a configuration similar to the base portion 161A and bulging portion 161B of the first signal terminal 161. Consequently, these signal terminals are electrically connected to the wiring substrate 81 by being pressed into one of the plurality of through-holes 811A. By adopting this configuration, the inverter device B can be made more compact.

As shown in FIG. 23, the plurality of support members 82 are located between the base portion 711 of the heat dissipation member 71 and the wiring substrate 81 in the first direction z. The wiring substrate 81 is supported by the plurality of support members 82. The plurality of support members 82 are columnar.

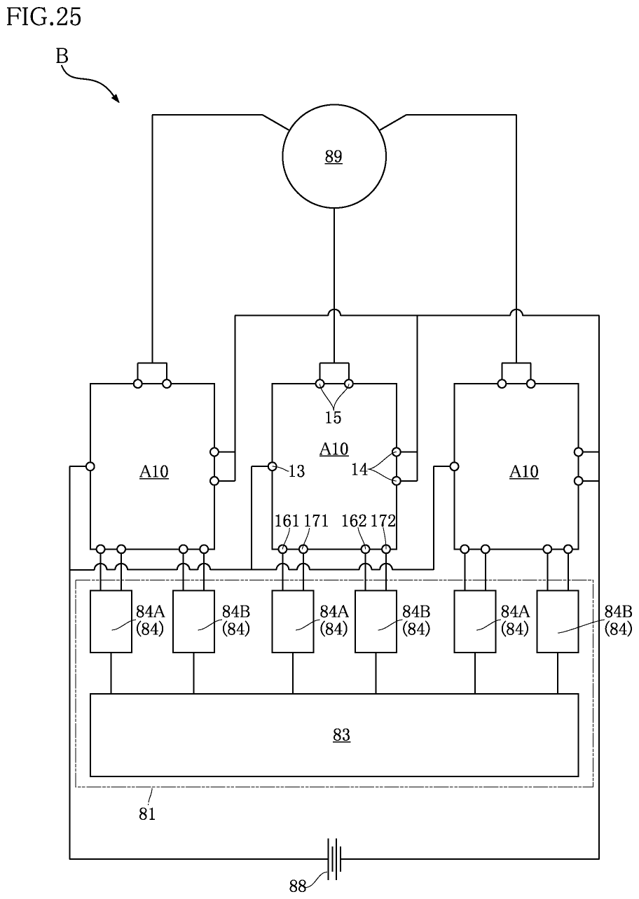

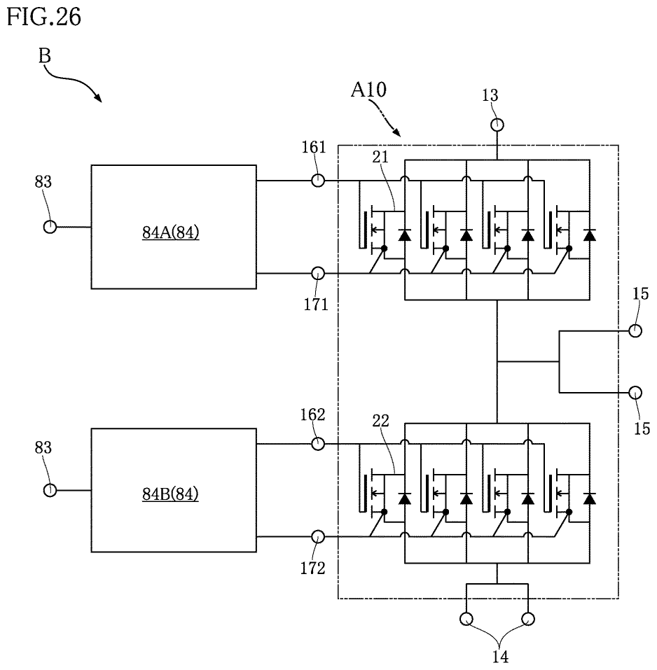

Next, with reference to FIGS. 25 and 26, the circuit of inverter device B will be described. The wiring substrate 81 is provided with the control circuit 83 electrically connected to the main-side wiring 812, and the plurality of drive circuits 84. The control circuit 83 is a microcomputer including a CPU (Central Processing Unit) and a memory. The control circuit 83 is electrically connected to the plurality of drive circuits 84 and is also connected to the outside. The control circuit 83 generates control signals for driving the plurality of drive circuits 84 based on input signals from the outside. The generation of control signals is performed, for example, based on PWM (Pulse Width Modulation) control. The generated control signals are output individually to the plurality of drive circuits 84.

Each of the plurality of drive circuits 84 generates a drive signal for driving one of the three semiconductor devices A10 based on the control signal input from the control circuit 83. The generated drive signal is output to either the first signal terminal 161 or the second signal terminal 162 of each of the three semiconductor devices A10.

As shown in FIG. 25, the plurality of drive circuits 84 includes three first drive circuits 84A and three second drive circuits 84B. As shown in FIG. 26, each of the three first drive circuits 84A drives the plurality of first semiconductor elements 21 of one of the three semiconductor devices A10. Each of the three first drive circuits 84A is individually electrically connected to the first signal terminal 161 and the third signal terminal 171 of each of the three semiconductor devices A10. As shown in FIG. 26, each of the three second drive circuits 84B drives the plurality of second semiconductor elements 22 in one of the three semiconductor devices A10. Each of the three second drive circuits 84B is individually electrically connected to the second signal terminal 162 and the fourth signal terminal 172 of each of the three semiconductor devices A10.

As shown in FIG. 25, the first power terminal 13 of each of the three semiconductor devices A10 is electrically connected to the positive terminal of the DC power supply 88. The two second power terminals 14 of each of the three semiconductor devices A10 are electrically connected to the negative terminal of the DC power supply 88. As a result, DC power is input to each of the three semiconductor devices A10. Furthermore, by driving the plurality of first semiconductor elements 21 and the plurality of second semiconductor elements 22 of each of the three semiconductor devices A10 by the plurality of drive circuits 84, three-phase AC power corresponding individually to the U-phase, V-phase, and W-phase is output from the two third power terminals 15 of each of the three semiconductor devices A10.

As shown in FIG. 25, the motor 89 is electrically connected to the two third power terminals 15 of each of the three semiconductor devices A10. The motor 89 is, for example, a three-phase induction motor. The three-phase AC power output from the two third power terminals 15 of each of the three semiconductor devices A10 is input to the motor 89. This drives the motor 89.

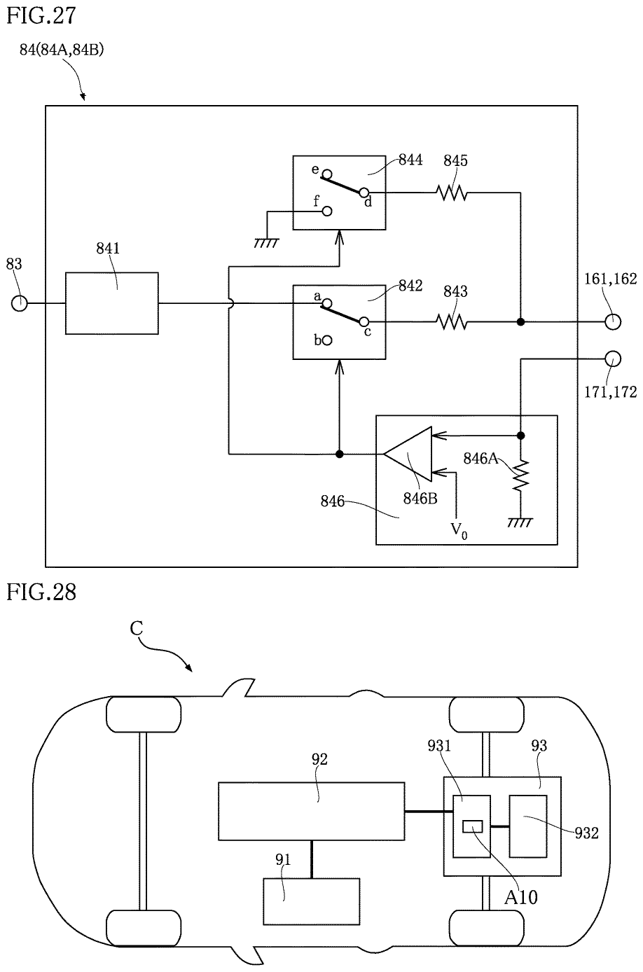

Next, with reference to FIG. 27, each of the plurality of drive circuits 84 will be described. Each of the plurality of drive circuits 84 includes an amplification circuit 841, a first switch circuit 842, a gate resistor 843, a second switch circuit 844, a current cutoff resistor 845, and an overcurrent detection circuit 846.

A control signal from the control circuit 83 is input to the amplification circuit 841. The amplification circuit 841 amplifies this control signal to generate a drive signal for driving one of the three semiconductor devices A10. The first switch circuit 842 has terminals a, b, and c. Terminals a and b are on the input side. Terminal c is on the output side. In the first switch circuit 842, the terminal c is connected to either the terminal a or the terminal b. The terminal a is connected to the amplification circuit 841. The terminal b is electrically open. The terminal c is electrically connected, via the gate resistor 843, to either the first signal terminal 161 or the second signal terminal 162 of one of the three semiconductor devices A10.

The second switch circuit 844 has terminals d, e, and f. The terminal d is on the input side. The terminals e and f are on the output side. In the second switch circuit 844, the terminal d is connected to either the terminal e or the terminal f. The terminal d is electrically connected to the first signal terminal 161 or the second signal terminal 162 of one of the three semiconductor devices A10 via a current cutoff resistor 845. In each of the plurality of drive circuits 84, the gate resistor 843 and the current cutoff resistor 845 are connected in parallel with respect to the first signal terminal 161 or the second signal terminal 162 of one of the three semiconductor devices A10. The terminal e is electrically open. The terminal f is grounded. The resistance value r2 of the current cutoff resistor 845 is greater than the resistance value r1 of the gate resistor 843.

The overcurrent detection circuit 846 controls the first switch circuit 842 and the second switch circuit 844. The overcurrent detection circuit 846 includes a current detection resistor 846A and a comparison circuit 846B. One end of the current detection resistor 846A is electrically connected to the third signal terminal 171 or the fourth signal terminal 172 of one of the three semiconductor devices A10. The other end of the current detection resistor 846A is grounded. The inter-terminal voltage of the current detection resistor 846A (voltage drop) corresponds to the drain-source voltage of each of the plurality of first semiconductor elements 21 in one of the three semiconductor devices A10, or the drain-source voltage of each of the plurality of second semiconductor elements 22 in one of the three semiconductor devices A10. The inter-terminal voltage of the current detection resistor 846A is applied to the comparison circuit 846B. The comparison circuit 846B determines whether the plurality of first semiconductor elements 21 or the plurality of second semiconductor elements 22 in any of the three semiconductor devices A10 is in an overcurrent state by comparing the inter-terminal voltage of the current detection resistor 846A with a reference voltage V₀. The comparison circuit 846B outputs a determination signal representing the result of the determination. Specifically, when the inter-terminal voltage of the current detection resistor 846A is greater than the reference voltage V₀, it determines that an overcurrent condition exists.

When not in an overcurrent state (normal state), in the second switch circuit 844, the terminal d is connected to the terminal e. As a result, the impedance of the terminal d of the second switch circuit 844 becomes sufficiently high. At the same time, in the first switch circuit 842, the terminal c is connected to the terminal a. As a result, the drive signal generated by the amplification circuit 841 is output via the gate resistor 843 to either the first signal terminal 161 or the second signal terminal 162 of one of the three semiconductor devices A10.

On the other hand, when in the overcurrent state, in the first switch circuit 842, the terminal c is connected to the terminal b. As a result, the impedance of the terminal c in the first switch circuit 842 becomes sufficiently high. Concurrently, in the second switch circuit 844, the terminal d is connected to the terminal f. As a result, the terminal d is grounded.

Therefore, when in the overcurrent state, the first signal terminal 161 or the second signal terminal 162 of any of the three semiconductor devices A10 is grounded via the current cutoff resistor 845. As a result, the gate-source voltage of each of the plurality of first semiconductor elements 21 in any one of the three semiconductor devices A10, or the gate-source voltage of each of the plurality of second semiconductor elements 22 in any one of the three semiconductor devices A10, is reduced. Furthermore, the short-circuit current between the drain and the source of each of the plurality of first semiconductor elements 21 in any of the three semiconductor devices A10 (hereinafter referred to as the “short-circuit current”), or the short-circuit current of each of the plurality of second semiconductor elements 22 in any of the three semiconductor devices A10, is interrupted. As a result, the plurality of drive circuits 84 provide overcurrent protection for the plurality of first semiconductor elements 21 and the plurality of second semiconductor elements 22. The interruption speed for the short-circuit current varies depending on the magnitude of the resistance value r2 of the current cutoff resistor 845. The larger the resistance value r2 is, the slower the interruption speed for the short-circuit current is.

Here, if the short-circuit current exceeds the short-circuit withstand capacity of each of the plurality of first semiconductor elements 21 and the plurality of second semiconductor elements 22, the first semiconductor element 21 or the second semiconductor element 22 may be destroyed while the overcurrent protection by the plurality of drive circuits 84 is still in progress. Therefore, for example, a measure may be taken to provide an internal resistance between the second electrode 212 and the first detection electrode 214 (or between the fourth electrode 222 and the second detection electrode 224) within each of the plurality of first semiconductor elements 21 or the plurality of second semiconductor elements 22. Thus, by reducing the gate-source voltage when the short-circuit current flows via this internal resistance, the destruction of the first semiconductor element 21 or the second semiconductor element 22 can be prevented more reliably.

Next, with reference to FIG. 28, the vehicle C equipped with the semiconductor device A10 will be described. The vehicle C is, for example, an electric vehicle (EV).

As shown in FIG. 28, the vehicle C is equipped with an on-board charger 91, a storage battery 92, and a drive system 93. The on-board charger 91 is supplied with power wirelessly from a power supply facility (not shown) installed outdoors. Alternatively, the means for supplying power from the power supply facility to the on-board charger 91 may be wired. The on-board charger 91 is configured with a step-up type DC-DC converter. The voltage of the power supplied to the on-board charger 91 is stepped up by said converter and then supplied to the storage battery 92. The stepped-up voltage is, for example, 600 V.

The drive system 93 drives the vehicle C. The drive system 93 includes an inverter 931 and a drive source 932. The semiconductor device A10 constitutes a part of the inverter 931. In addition, the inverter device B described above may be applied as a configuration of the inverter 931. The electrical power stored in the storage battery 92 is supplied to the inverter 931. The electrical power supplied from the storage battery 92 to the inverter 931 is DC power. Furthermore, unlike the power system shown in FIG. 28, a step-up DC-DC converter may be further provided between the storage battery 92 and the inverter 931. The inverter 931 converts DC power into AC power. The inverter 931, including the semiconductor device A10, is electrically connected to the drive source 932. The drive source 932 includes an AC motor and a transmission. When AC power converted by the inverter 931 is supplied to the drive source 932, the AC motor rotates, and this rotation is transmitted to the transmission. The transmission reduces the rotational speed transmitted from the AC motor as appropriate and rotates the drive shaft of the vehicle C. This causes the vehicle C to move. To drive the vehicle C, it is necessary to freely control the rotational speed of the AC motor based on information such as the amount of variation in the accelerator pedal. Therefore, the semiconductor device A10 in the inverter 931 is necessary to output AC power with a frequency appropriately varied to correspond to the required rotational speed of the AC motor.

Next, the operational effects of the semiconductor device A10 will be explained.

The semiconductor device A10 includes the heat dissipation member 71, the base material 11 including the heat dissipation layer 113, the first conductive layer 121, the first semiconductor element 21, and the bonding layer 72. In the first direction z, the base material 11 faces the heat dissipation member 71. The bonding layer 72 bonds the heat dissipation member 71 to the heat dissipation layer 113. The bonding layer 72 includes a sintered body of metal particles. In the bonding layer 72, a void portion 73 extending therethrough in the first direction z is provided. Here, in the fourth step S4 of the manufacturing process for the semiconductor device A10, when the bonding layer 72 is formed by sintering the bonding material 79, shear stress caused by the heat of the sintering is generated at both the interface between the bonding layer 72 and the heat dissipation member 71, and the interface between the bonding layer 72 and the heat dissipation layer 113. Therefore, by adopting this configuration, the flow of shear stress in any direction orthogonal to the first direction z is interrupted by the void portion 73. Consequently, even if delamination of the base material 11 from the heat dissipation member 71 occurs, the progression of the delamination is restrained by the void portion 73. Therefore, according to this configuration, it is possible to suppress delamination of the base material 11 from the heat dissipation member 71 in the semiconductor device A10.

The void portion 73 is exposed to the outside of the semiconductor device A10. By adopting this configuration, the degree of drying of the bonding material 79 becomes more uniform during the third step S3 of the semiconductor device A10's manufacturing process, thereby enabling the effective removal of the solvent contained in the bonding material 79.

As viewed in the first direction z, the heat dissipation layer 113 of the base material 11 has a first edge 113A and a second edge 113B. As viewed in the first direction z, the first edge 113A or its extended line and the second edge 113B or its extended line intersect at the first intersection point P1. As viewed in the first direction z, the void portion 73 is located between the first intersection point P1 and the bonding layer 72. Consequently, as viewed in the first direction z, the void portion 73 is positioned at the corner of the heat dissipation layer 113. Here, shear stress caused by the heat of the sintering of the bonding material 79 tends to concentrate at the corner of the heat dissipation layer 113. Therefore, by adopting this configuration, delamination of the base material 11 from the heat dissipation member 71 can be effectively suppressed.

The bonding layer 72 includes the first bonding portion 721 and the second bonding portion 722, which are spaced apart from each other in the second direction x. Furthermore, the bonding layer 72 includes the third bonding portion 723, which is spaced apart from the first bonding portion 721 and the second bonding portion 722 in a direction orthogonal to the first direction z. By adopting this configuration, the distribution of shear stress caused by the heat of the sintering of the bonding material 79 can be more effectively dispersed.

### Second Embodiment

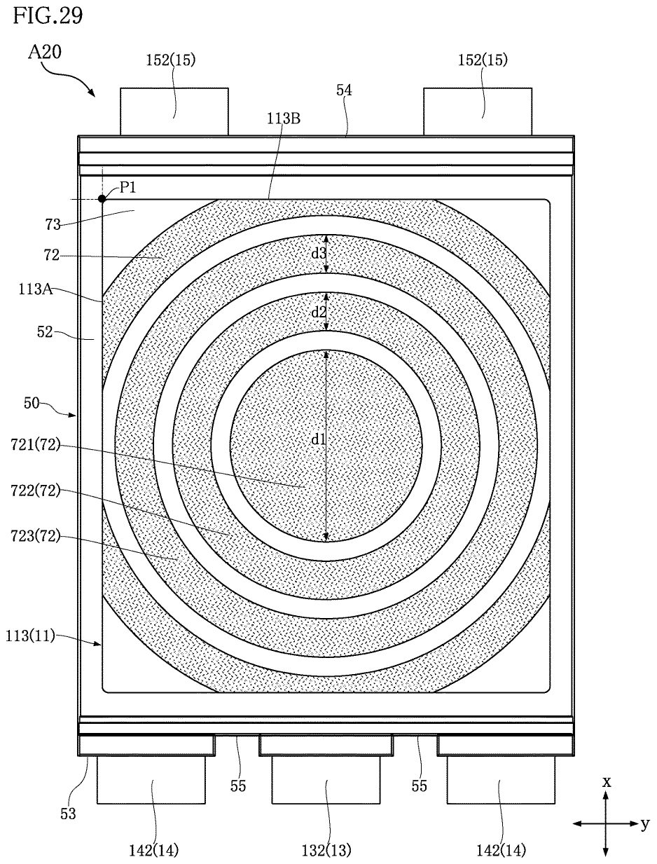

With reference to FIG. 29, a semiconductor device A20 according to a second embodiment of the present disclosure will be described. In this figure, the same reference numerals are assigned to elements identical or similar to those of the semiconductor device A10 described above, and redundant descriptions are omitted. Here, for ease of understanding, the heat dissipation member 71 is omitted from FIG. 29. FIG. 29 corresponds to FIG. 14, which shows the semiconductor device A10.

In the semiconductor device A20, the configuration of the bonding layer 72 differs from that of the semiconductor device A10.

As shown in FIG. 29, the second bonding portion 722 of the bonding layer 72 surrounds the first bonding portion 721 of the bonding layer 72. The third bonding portion 723 of the bonding layer 72 surrounds the second bonding portion 722. The dimension d1 of the first bonding portion 721 in the second direction x is larger than both the dimension d2 of the second bonding portion 722 in the second direction x and the dimension d3 of the third bonding portion 723 in the second direction x. As viewed in the first direction z, the first bonding portion 721 is circular. As viewed in the first direction z, the second bonding portion 722 and the third bonding portion 723 are each annular.

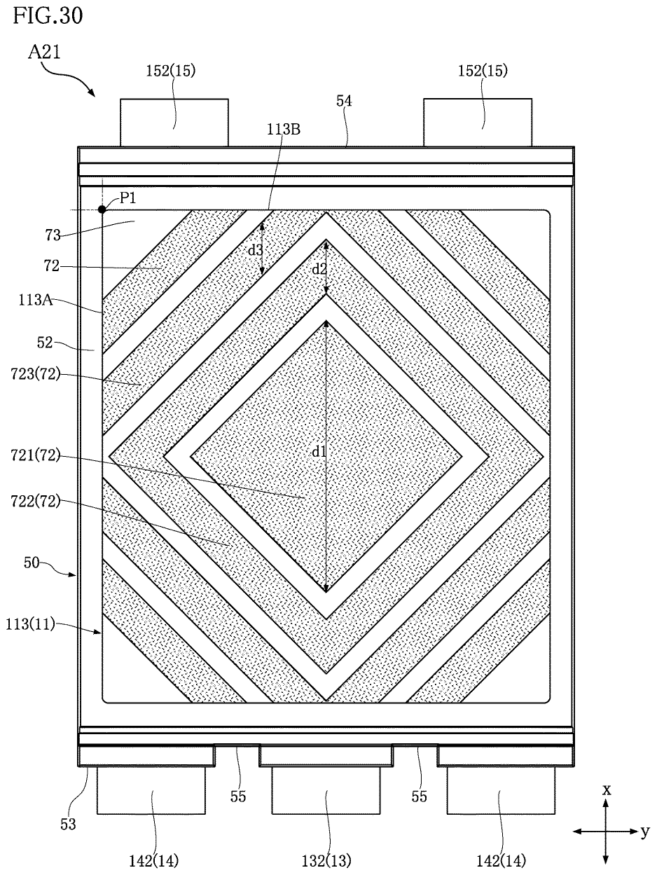

Next, with reference to FIG. 30, the semiconductor device A21 according to a variation of the second embodiment of the present disclosure will be described. FIG. 30 corresponds to FIG. 29, which shows the semiconductor device A20. In the semiconductor device A21, the configuration of the bonding layer 72 differs from that of the semiconductor device A20.

As shown in FIG. 30, as viewed in the first direction z, the first bonding portion 721 of the bonding layer 72 is rectangular. As viewed in the first direction z, the second bonding portion 722 and the third bonding portion 723 of the bonding layer 72 are each frame-shaped.

Next, the operational effects of the semiconductor device A20 will be described.

The semiconductor device A20 includes the heat dissipation member 71, the base material 11 including the heat dissipation layer 113, the first conductive layer 121, the first semiconductor element 21, and the bonding layer 72. In the first direction z, the base material 11 faces the heat dissipation member 71. The bonding layer 72 bonds the heat dissipation member 71 to the heat dissipation layer 113. The bonding layer 72 includes a sintered body of metal particles. In the bonding layer 72, a void portion 73 penetrating the bonding layer 72 in the first direction z is provided. Therefore, according to this configuration, it is possible to suppress delamination of the base material 11 from the heat dissipation member 71 in the semiconductor device A20 as well. Furthermore, since the semiconductor device A20 incorporates a configuration common to the semiconductor device A10, it exhibits the same operational effects as the semiconductor device A10.

In the semiconductor device A20, the second bonding portion 722 of the bonding layer 72 surrounds the first bonding portion 721 of the bonding layer 72. This results in a configuration where the void portion 73 surrounds the first bonding portion 721. By adopting this configuration, the direction of the flow of the shear stress caused by the heat from the sintering of the bonding material 79, which is divided by the void portion 73, becomes radial in a direction perpendicular to the first direction z. This allows for more effective suppression of delamination of the base material 11 from the heat dissipation member 71.

### Third Embodiment

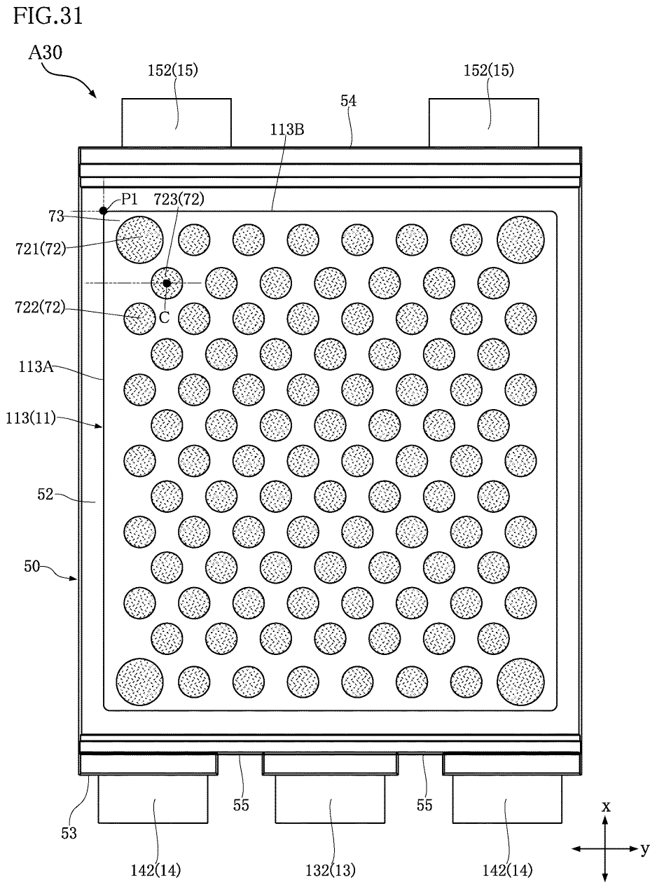

With reference to FIG. 31, the semiconductor device A30 according to the third embodiment of the present disclosure will be described. In this figure, the same reference numerals are assigned to elements identical or similar to those of the semiconductor device A10 described above, and redundant descriptions are omitted. Here, for ease of understanding, the heat dissipation member 71 is omitted from FIG. 31. FIG. 31 corresponds to FIG. 14, which shows the semiconductor device A10.

In the semiconductor device A30, the configuration of the bonding layer 72 differs from that of the semiconductor device A10.

As shown in FIG. 31, the relative arrangement of the first bonding portion 721, the second bonding portion 722, and the third bonding portion 723 of the bonding layer 72 in the semiconductor device A30 corresponds to that of the semiconductor device A10. As viewed in the first direction z, the first bonding portion 721 is located closer to the first intersection point P1 than the second bonding portion 722. As viewed in the first direction z, the area of the first bonding portion 721 is larger than the area of the second bonding portion 722.

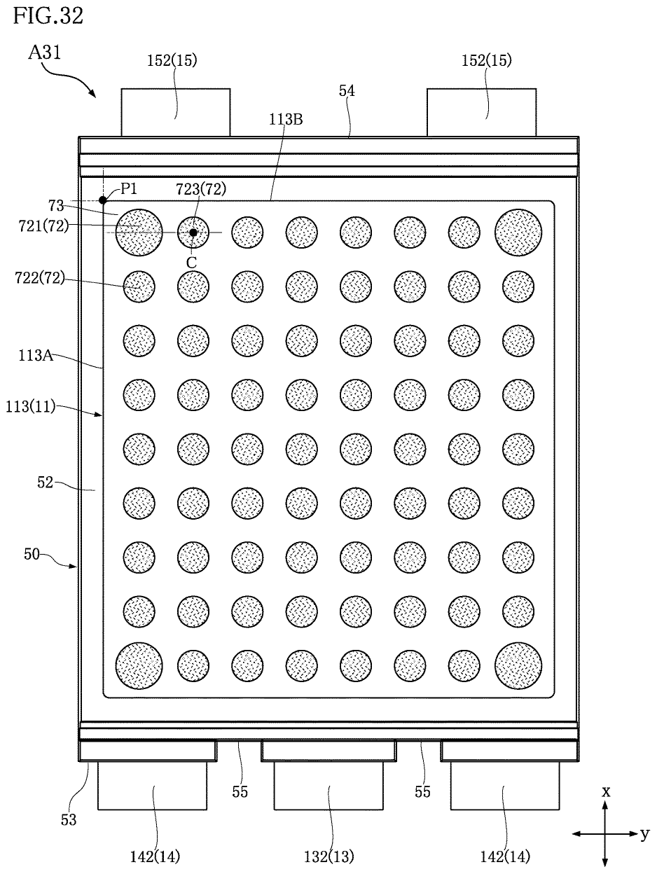

Next, with reference to FIG. 32, the semiconductor device A31 according to a variation of the third embodiment of the present disclosure will be described. FIG. 32 corresponds to FIG. 31, which shows the semiconductor device A30. In the semiconductor device A31, the configuration of the bonding layer 72 differs from that of the semiconductor device A30.

As shown in FIG. 32, the relative arrangement of the first bonding portion 721, the second bonding portion 722, and the third bonding portion 723 of the bonding layer 72 in the semiconductor device A31 corresponds to that of the semiconductor device A11. As viewed in the first direction z, the first bonding portion 721 is located closer to the first intersection point P1 than the second bonding portion 722. As viewed in the first direction z, the area of the first bonding portion 721 is larger than that of the second bonding portion 722.

Next, the operational effects of the semiconductor device A30 will be explained.

The semiconductor device A30 includes the heat dissipation member 71, the base material 11 including the heat dissipation layer 113, the first conductive layer 121, the first semiconductor element 21, and the bonding layer 72. In the first direction z, the base material 11 faces the heat dissipation member 71. The bonding layer 72 bonds the heat dissipation member 71 to the heat dissipation layer 113. The bonding layer 72 includes a sintered body of metal particles. In the bonding layer 72, the void portion 73 penetrating the bonding layer 72 in the first direction z is provided. Therefore, according to this configuration, in the semiconductor device A30 as well, it is possible to suppress delamination of the base material 11 from the heat dissipation member 71. Furthermore, the semiconductor device A30 exhibits the same operational effects as the semiconductor device A10 by incorporating a configuration common to the semiconductor device A10.

In the semiconductor device A30, as viewed in the first direction z, the first bonding portion 721 of the bonding layer 72 is located closer to the first intersection point P1 than the second bonding portion 722 of the bonding layer 72. As viewed in the first direction z, the area of the first bonding portion 721 is larger than that of the second bonding portion 722. By adopting this configuration, the first bonding portion 721, which has a relatively large area as viewed in the first direction z, is located near the corner of the heat dissipation layer 113 of the base material 11, where shear stress caused by the sintering of the bonding material 79 tends to concentrate. This reduces the concentration of shear stress at the interfaces between the first bonding portion 721 and each of the heat dissipation member 71 and the heat dissipation layer 113. Consequently, this more effectively suppresses delamination of the base material 11 from the heat dissipation member 71.

### Fourth Embodiment

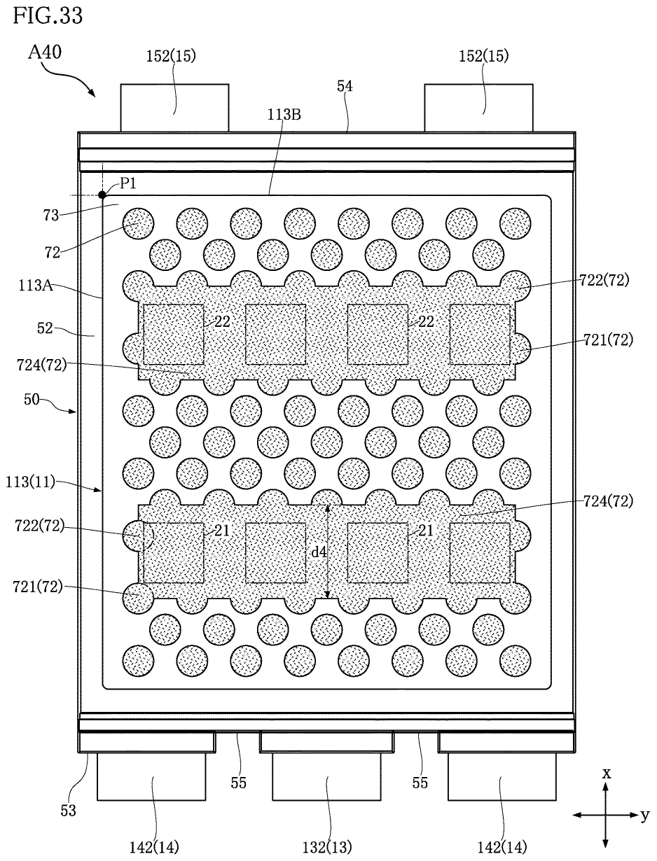

With reference to FIG. 33, the semiconductor device A40 according to the fourth embodiment of the present disclosure will be described. In this figure, the same reference numerals are assigned to elements identical or similar to those of the semiconductor device A10 described above, and redundant descriptions are omitted. Here, for ease of understanding, the heat dissipation member 71 is omitted from FIG. 33. FIG. 33 corresponds to FIG. 14 showing the semiconductor device A10.

In the semiconductor device A40, the configuration of the bonding layer 72 differs from that of the semiconductor device A10.

As shown in FIG. 33, the configuration of the first bonding portion 721, the second bonding portion 722, and the third bonding portion 723 of the bonding layer 72 in the semiconductor device A40 corresponds to that of the semiconductor device A10. The bonding layer 72 includes two connecting portions 724. The two connecting portions 724 are spaced apart from each other in the second direction x. Each of the two connecting portions 724 is a strip extending in the third direction y. Each of the two connecting portions 724 is connected to the first bonding portion 721 and the second bonding portion 722 of the bonding layer 72. The dimension d4 in the second direction x of each of the two connecting portions 724 is larger than the dimension in the second direction x of each of the first bonding portion 721 and the second bonding portion 722. As viewed in the first direction z, the plurality of first semiconductor elements 21 overlap one of the two connecting portions 724. As viewed in the first direction z, the plurality of second semiconductor elements 22 overlap the other one of the two connecting portions 724.

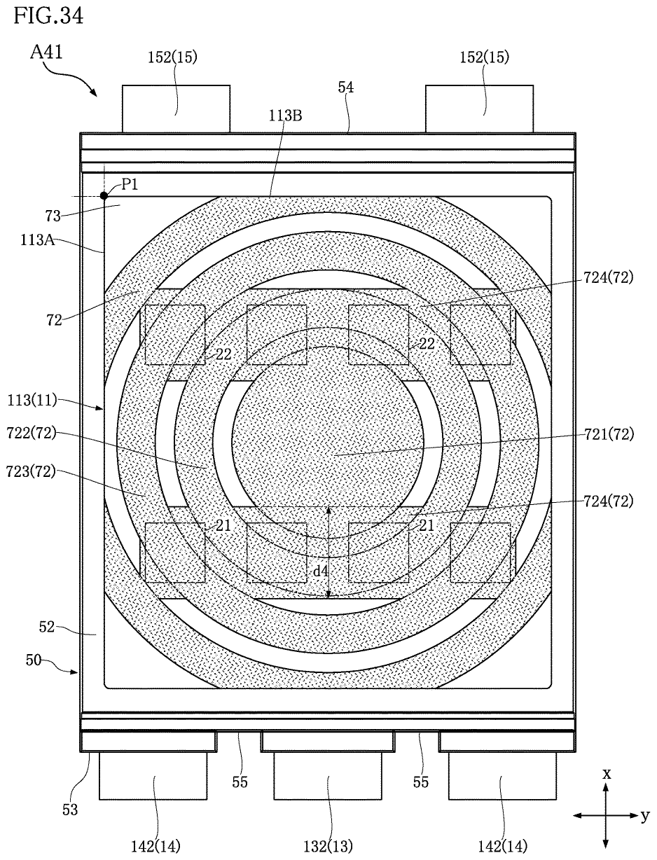

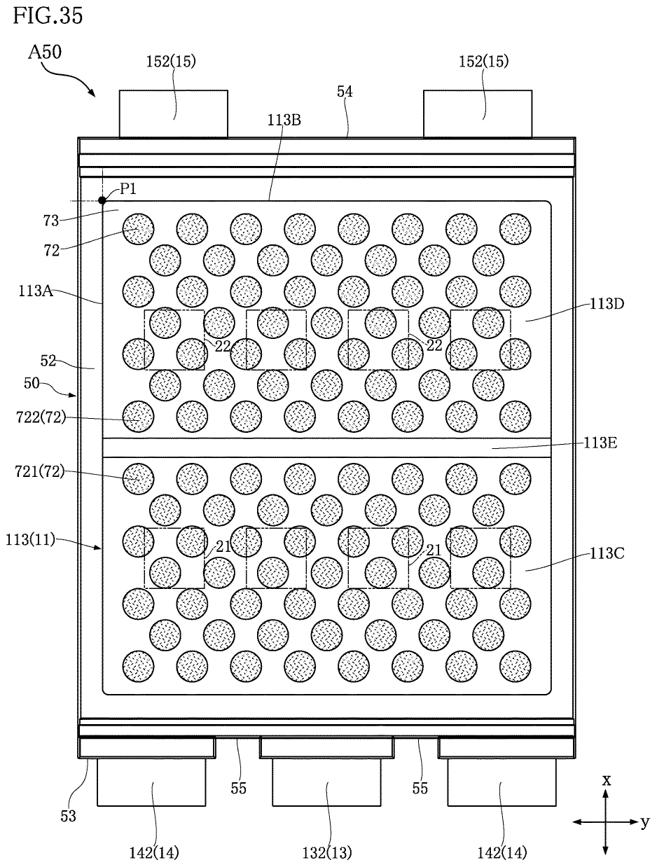

Next, with reference to FIG. 34, the semiconductor device A41 according to a variation of the fourth embodiment of the present disclosure will be described. FIG. 34 corresponds to FIG. 33, which shows the semiconductor device A40. In the semiconductor device A41, the configuration of the bonding layer 72 differs from that of the semiconductor device A40.

As shown in FIG. 34, the configuration of the first bonding portion 721, the second bonding portion 722, and the third bonding portion 723 of the bonding layer 72 in the semiconductor device A41 corresponds to that of the semiconductor device A20. The bonding layer 72 includes two connecting portions 724. The configuration of the two connecting portions 724 is the same as that of the semiconductor device A40.

Next, the operational effects of the semiconductor device A40 will be described.

The semiconductor device A40 includes the heat dissipation member 71, the base material 11 including the heat dissipation layer 113, the first conductive layer 121, the first semiconductor element 21, and the bonding layer 72. In the first direction z, the base material 11 faces the heat dissipation member 71. The bonding layer 72 bonds the heat dissipation member 71 to the heat dissipation layer 113. The bonding layer 72 includes a sintered body of metal particles. In the bonding layer 72, the void portion 73 penetrating the bonding layer 72 in the first direction z is provided. Therefore, according to this configuration, in the semiconductor device A40 as well, it is possible to suppress delamination of the base material 11 from the heat dissipation member 71. Furthermore, since the semiconductor device A40 incorporates a configuration common to the semiconductor device A10, it exhibits the same operational effects as the semiconductor device A10.

In the semiconductor device A40, the bonding layer 72 includes the connecting portion 724 connected to the first bonding portion 721 and the second bonding portion 722. The dimension d4 of the connecting portion 724 in the second direction x is larger than the dimension in the second direction x of each of the first bonding portion 721 and the second bonding portion 722. By adopting this configuration, as viewed in the first direction z, the area of the bonding layer 72 increases. This allows for an improvement in the bonding strength between the heat dissipation member 71 and the heat dissipation layer 113 of the base material 11.

In the above case, as viewed in the first direction z, the first semiconductor element 21 overlaps the connecting portion 724. By adopting this configuration, during use of the semiconductor device A40, heat generated by the first semiconductor element 21 can be smoothly conducted from the heat dissipation layer 113 of the base material 11 to the heat dissipation member 71 via the connecting portion 724.

### Fifth Embodiment

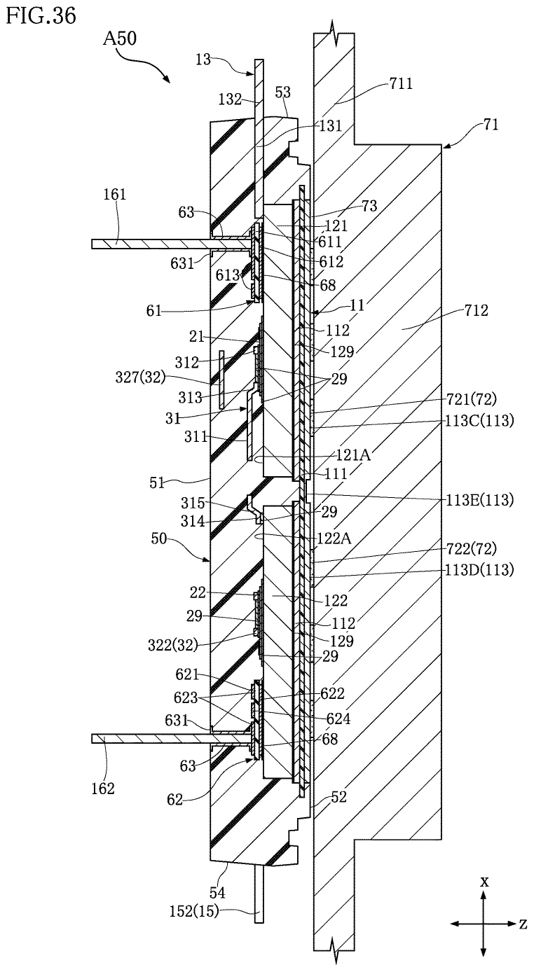

With reference to FIGS. 35 and 36, the semiconductor device A50 according to the fifth embodiment of the present disclosure will be described. In these figures, the same reference numerals are assigned to elements identical or similar to those of the semiconductor device A10 described above, and redundant descriptions are omitted. Here, in FIG. 35, for ease of understanding, the heat dissipation member 71 is omitted. FIG. 35 corresponds to FIG. 14, which shows the semiconductor device A10. FIG. 36 corresponds to FIG. 9, which shows the semiconductor device A10.

In the semiconductor device A50, the configuration of the heat dissipation layer 113 of the base material 11 differs from that of the semiconductor device A10.

As shown in FIGS. 35 and 36, the heat dissipation layer 113 of the base material 11 has a first surface 113C and a second surface 113D facing the base portion 711 of the heat dissipation member 71. The first surface 113C and the second surface 113D are spaced apart from each other in the second direction x. The first bonding portion 721 of the bonding layer 72 is bonded to the first surface 113C. A second bonding portion 722 of the bonding layer 72 is bonded to the second surface 113D.

As shown in FIGS. 35 and 36, the heat dissipation layer 113 of the base material 11 is provided with a groove portion 113E that is recessed in the first direction z. The groove portion 113E extends in the third direction y. The first surface 113C and the second surface 113D of the heat dissipation layer 113 are located on opposite sides of each other with respect to the groove portion 113E. As viewed in the first direction z, the plurality of first semiconductor elements 21 overlap the first surface 113C. As viewed in the first direction z, the plurality of second semiconductor elements 22 overlap the second surface 113D.

Next, the operational effects of the semiconductor device A50 will be described.

The semiconductor device A50 includes the heat dissipation member 71, the base material 11 including the heat dissipation layer 113, the first conductive layer 121, the first semiconductor element 21, and the bonding layer 72. In the first direction z, the base material 11 faces the heat dissipation member 71. The bonding layer 72 bonds the heat dissipation member 71 to the heat dissipation layer 113. The bonding layer 72 includes a sintered body of metal particles. In the bonding layer 72, the void portion 73 penetrating the bonding layer 72 in the first direction z is provided. Therefore, according to this configuration, in the semiconductor device A50 as well, it is possible to suppress delamination of the base material 11 from the heat dissipation member 71. Furthermore, since the semiconductor device A50 incorporates a configuration common to the semiconductor device A10, it exhibits the same operational effects as the semiconductor device A10.

In the semiconductor device A50, the groove portion 113E recessed in the first direction z is provided in the heat dissipation layer 113 of the base material 11. By adopting this configuration, the flow of shear stress caused by the heat from the sintering of the bonding material 79 in any direction orthogonal to the first direction z is interrupted not only by the void portion 73 but also by the groove portion 113E. Consequently, even if delamination of the base material 11 from the heat dissipation member 71 occurs, the progression of the delamination is restricted by the void portion 73 and the groove portion 113E. Therefore, delamination of the base material 11 from the heat dissipation member 71 can be more effectively suppressed.

The heat dissipation layer 113 of the base material 11 has the first surface 113C and the second surface 113D facing the heat dissipation member 71. The first surface 113C and the second surface 113D are positioned on opposite sides of each other with respect to the groove portion 113E. As viewed in the first direction z, the first semiconductor element 21 overlaps the first surface 113C. As viewed in the first direction z, the second semiconductor element 22 overlaps the second surface 113D. By adopting this configuration, when the semiconductor device A50 is in use, heat generated by each of the first semiconductor element 21 and the second semiconductor element 22 can be transmitted to the heat dissipation member 71 without being impeded by the groove portion 113E provided in the heat dissipation layer 113.

The present disclosure is not limited to the embodiments described above. The specific configurations of the respective parts of the present disclosure are subject to various design modifications.

The present disclosure includes the embodiments described in the following clauses.

### Clause 1

A semiconductor device, comprising:
a heat dissipation member;
a base material including a heat dissipation layer facing the heat dissipation member in a first direction;
a first conductive layer positioned opposite to the heat dissipation member with respect to the base material, and bonded to the base material;
a first semiconductor element bonded to the first conductive layer; and
a bonding layer bonding the heat dissipation member to the heat dissipation layer,
wherein the bonding layer includes a sintered body of metal particles, and
the bonding layer is provided with a void portion penetrating the bonding layer in the first direction.

### Clause 2

The semiconductor device according to Clause 1, wherein the bonding layer includes a first bonding portion and a second bonding portion spaced apart from each other in a second direction orthogonal to the first direction.

### Clause 3

The semiconductor device according to Clause 2, wherein the void portion is exposed to the outside.

### Clause 4

The semiconductor device according to Clause 3,
wherein as viewed in the first direction, the heat dissipation layer has a first edge and a second edge,
the first edge extends in the second direction,
the second edge extends in a direction perpendicular to the first direction and different from the second direction,
as viewed in the first direction, the first edge or its extended line and the second edge or its extended line intersect at a first intersection point, and
as viewed in the first direction, the void portion includes a portion located between the first intersection point and the bonding layer.

### Clause 5

The semiconductor device according to Clause 4,
wherein as viewed in the first direction, the first bonding portion is located closer to the first intersection point than the second bonding portion, and
as viewed in the first direction, an area of the first bonding portion is larger than an area of the second bonding portion.

### Clause 6

The semiconductor device according to Clause 3,
wherein the first bonding portion and the second bonding portion are adjacent to each other, and
the bonding layer includes a third bonding portion spaced apart from the first bonding portion and the second bonding portion in a direction orthogonal to the first direction.

### Clause 7

The semiconductor device according to Clause 6,
wherein the third bonding portion is located adjacent to the first bonding portion and the second bonding portion in a direction perpendicular to the first direction, and
as viewed in the first direction, a virtual line passing through a center of the third bonding portion and extending in a third direction orthogonal to both the first direction and the second direction overlaps the void portion located between the first bonding portion and the second bonding portion.

### Clause 8

The semiconductor device according to Clause 6,
wherein the third bonding portion is located adjacent to the first bonding portion in a third direction orthogonal to both the first direction and the second direction, and
as viewed in the first direction, a virtual line passing through a center of the third bonding portion and extending in the third direction overlaps the first bonding portion.

### Clause 9

The semiconductor device according to Clause 6, wherein as viewed in the first direction, areas of the first bonding portion, the second bonding portion, and the third bonding portion are equal to one another.

### Clause 10

The semiconductor device according to Clause 3, wherein the second bonding portion surrounds the first bonding portion.

### Clause 11

The semiconductor device according to Clause 10, wherein a dimension of the first bonding portion in the second direction is larger than a dimension of the second bonding portion in the second direction.

### Clause 12

The semiconductor device according to Clause 3,
wherein the bonding layer includes a connecting portion connecting the first bonding portion and the second bonding portion, and
a dimension of the connecting portion in the second direction is greater than a dimension of each of the first bonding portion and the second bonding portion in the second direction.

### Clause 13

The semiconductor device according to Clause 12, wherein as viewed in the first direction, the first semiconductor element overlaps the connecting portion.

### Clause 14

The semiconductor device according to one of Clauses 3 to 13,
wherein the base material includes an insulating layer located on a side opposite to the heat dissipation member with respect to the heat dissipation layer, and
the first conductive layer is bonded to the insulating layer.

### Clause 15

The semiconductor device according to Clause 14, further comprising:
a second conductive layer positioned on the same side as the first conductive layer with respect to the base material and bonded to the insulating layer; and
a second semiconductor element conductively bonded to the second conductive layer,
wherein the first semiconductor element is conductively bonded to the first conductive layer, and
the second semiconductor element is conductively connected to the first semiconductor element.

### Clause 16

The semiconductor device according to Clause 15, wherein the metal particles contain silver.

### Clause 17

The semiconductor device according to Clause 15, wherein conductive bonding of the first semiconductor element to the first conductive layer and conductive bonding of the second semiconductor element to the second conductive layer are performed using liquid metal.

### Clause 18

A method for manufacturing a semiconductor device, comprising:
a first step of bonding a first conductive layer to a base material including a heat dissipation layer such that the first conductive layer is positioned on a side of the base material opposite to the heat dissipation layer in a first direction;
a second step of conductively bonding a first semiconductor element to the first conductive layer;
a third step of placing a bonding material on one side, in the first direction, of either a heat dissipation member or the heat dissipation layer; and
a fourth step of bonding the heat dissipation member to the heat dissipation layer by sintering the bonding material,
wherein the bonding material includes metal particles, and
in the third step, the bonding material is provided with a void portion penetrating the bonding material in the first direction.

### Clause 19

The method according to Clause 18,
wherein in the third step, the bonding material is arranged to include a first portion and a second portion spaced apart from each other in a direction orthogonal to the first direction, and
in the third step, the void portion is formed so as to be exposed to the outside of the bonding material in a direction orthogonal to the first direction.

### Clause 20

The method according to Clause 18, wherein conductive bonding of the first semiconductor element to the first conductive layer is made using liquid metal.

### Clause 21

An inverter device, comprising:
a heat dissipation member;
a base material including a heat dissipation layer facing the heat dissipation member in a first direction;
a first conductive layer and a second conductive layer positioned on a side opposite to the heat dissipation member with respect to the base material and bonded to the base material;
a first semiconductor element conductively bonded to the first conductive layer;
a second semiconductor element conductively bonded to the second conductive layer;
a first signal terminal conductively connected to the first semiconductor element;
a second signal terminal conductively connected to the second semiconductor element;
a wiring substrate conductively connected individually to the first signal terminal and the second signal terminal; and
a bonding layer bonding the heat dissipation member to the heat dissipation layer,
wherein the bonding layer includes a sintered body of metal particles, and
the bonding layer is provided with a void portion penetrating the bonding layer in the first direction.

### Clause 22

The inverter device according to Clause 21, wherein the conductive bonding of the first semiconductor element to the first conductive layer and the conductive bonding of the second semiconductor element to the second conductive layer are performed using liquid metal.

### Clause 23

A vehicle comprising:
a drive source; and
the semiconductor device according to one of Clauses 15 to 17,
wherein the semiconductor device is conductively connected to the drive source.

### Clause 24

The semiconductor device according to Clause 6, wherein as viewed in the first direction, each of the first bonding portion, the second bonding portion, and the third bonding portion is circular.

### Clause 25

The semiconductor device according to Clause 6, wherein as viewed in the first direction, each of the first bonding portion, the second bonding portion, and the third bonding portion is rectangular.

### Clause 26

The semiconductor device according to Clause 11,
wherein the bonding layer includes a third bonding portion that surrounds the second bonding portion, and
a dimension of the first bonding portion in the second direction is greater than a dimension of the third bonding portion in the second direction.

### Clause 27

The semiconductor device according to Clause 26,
wherein as viewed in the first direction, the first bonding portion is circular, and
as viewed in the first direction, each of the second bonding portion and the third bonding portion is annular.

### Clause 28

The semiconductor device according to Clause 26 or 27,
wherein the bonding layer includes connecting portions connected to the first bonding portion, the second bonding portion, and the third bonding portion, and
a dimension of each connecting portion in the second direction is greater than a dimension of each of the second bonding portion and the third bonding portion in the second direction.

### Clause 29

The semiconductor device according to one of Clauses 15 to 17,
wherein the heat dissipation layer has a first surface and a second surface facing the heat dissipation member,
the first surface and the second surface are spaced apart from each other in the second direction,
the first bonding portion is bonded to the first surface, and
the second bonding portion is bonded to the second surface.

### Clause 30

The semiconductor device according to Clause 29,
wherein as viewed in the first direction, the first semiconductor element overlaps the first surface, and
as viewed in the first direction, the second semiconductor element overlaps the second surface.

### Clause 31

The semiconductor device according to Clause 30,
wherein the heat dissipation layer is provided with a groove portion recessed in the first direction, and
the first surface and the second surface are positioned on opposite sides of each other with respect to the groove portion.

### Clause 32

The semiconductor device according to one of Clauses 15 to 17, wherein the metal particles contain copper.

### Clause 33

The semiconductor device according to one of Clauses 15 to 17, further comprising:
a first terminal conductively connected to the first conductive layer; and
a second terminal conductively connected to the second conductive layer.

### Clause 34

The semiconductor device according to Clause 33, further comprising a sealing resin covering the first semiconductor element and the second semiconductor element,
wherein the heat dissipation layer, the first terminal, and the second terminal are exposed from the sealing resin.

### Clause 35

The method according to Clause 19 or 20, wherein the metal particles contain silver.

### Clause 36

A vehicle comprising:
a drive source; and
an inverter device according to Clause 21 or 22,
wherein the inverter device is conductively connected to the drive source.

### REFERENCE NUMERALS

A10 to A50: Semiconductor device B: Inverter device
C: Vehicle S1 to S4: First to Fourth steps
11: Base material 111: Insulating layer
112: Support layer 113: Heat dissipation layer
113A, 113B: First edge, Second edge
113C, 113D: First surface, Second surface
113E: Groove portion 121: First conductive layer
121A: First main surface 122: Second conductive layer
122A: Second main surface 129: First bonding layer
13: First power terminal 131: Covered portion
132: Exposed portion 14: Second power terminal
141: Covered portion 142: Exposed portion
15: Third power terminal 151: Covered portion
152: Exposed portion 161: First signal terminal
161A: Base portion 161B: Bulging portion
162: Second signal terminal 171: Third signal terminal
172: Fourth signal terminal 181: Fifth signal terminal
182: Sixth signal terminal 19: Seventh signal terminal
21: First semiconductor element 211: First electrode
212: Second electrode 213: First gate electrode
214: First detection electrode 22: Second semiconductor element
221: Third electrode 222: Fourth electrode
223: Second gate electrode 224: Second detection electrode
23: Thermistor 29: Conductive bonding layer
31: First conductive connection member 311: First main portion
312: First bonding portion 313: First connecting portion
314: Second bonding portion 315: Second connecting portion
32: Second conductive connection member 321: Second main portion
322: Third bonding portion 323: Third connecting portion
324: Fourth bonding portion 325: Fourth connecting portion
326: Intermediate portion 327: Crossbeam portion
41 to 47: First wire to Seventh wire 50: Sealing resin
51: Top surface 52: Bottom surface
53, 54: First side surface, Second side surface 55: Recess
61: First wiring 611: First mounting layer
612: First metal layer 613: First gate wiring layer
614: First detection wiring layer 615: First temperature detection wiring layer
616: Second detection wiring layer 62: Second wiring
621: Second mounting layer 622: Second metal layer
623: Second gate wiring layer 624: Third detection wiring layer
625: Second temperature detection wiring layer 626: Fourth detection wiring layer
63: Sleeve 631: End face
68, 69: Second bonding layer, Third bonding layer 71: Heat dissipation member
711: Base portion 712: Heat dissipation portion
72: Bonding layer 721 to 723: First bonding portion to Third bonding portion
724: Connecting portion 73: Void portion
79: Bonding material 791, 792: First portion, Second portion
81: Wiring substrate 811: Substrate
811A: Through-hole 812: Main-side wiring
813: Back-side wiring 814: Internal wiring
82: Support member 83: Control circuit
84: Drive circuit 84A: First drive circuit
84B: Second drive circuit 841: Amplifier circuit
842: First switch circuit 843: Gate resistor
844: Second switch circuit 845: Current cutoff resistor
846: Overcurrent detection circuit 846A: Current detection resistor
846B: Comparison circuit 88: DC power supply
89: Motor 91: On-board charger
92: Storage battery 93: Drive system
931: Inverter 932: Drive source
z: First direction x: Second direction
y: Third direction

1. A semiconductor device, comprising:
a heat dissipation member;
a base material including a heat dissipation layer facing the heat dissipation member in a first direction;
a first conductive layer positioned opposite to the heat dissipation member with respect to the base material, and bonded to the base material;
a first semiconductor element bonded to the first conductive layer; and
a bonding layer bonding the heat dissipation member to the heat dissipation layer,
wherein the bonding layer includes a sintered body of metal particles, and
the bonding layer is provided with a void portion penetrating the bonding layer in the first direction.

2. The semiconductor device according to claim 1, wherein the bonding layer includes a first bonding portion and a second bonding portion spaced apart from each other in a second direction orthogonal to the first direction.

3. The semiconductor device according to claim 2, wherein the void portion is exposed to the outside.

4. The semiconductor device according to claim 3,
wherein as viewed in the first direction, the heat dissipation layer has a first edge and a second edge,
the first edge extends in the second direction,
the second edge extends in a direction perpendicular to the first direction and different from the second direction,
as viewed in the first direction, the first edge or its extended line and the second edge or its extended line intersect at a first intersection point, and
as viewed in the first direction, the void portion includes a portion located between the first intersection point and the bonding layer.

5. The semiconductor device according to claim 4,
wherein as viewed in the first direction, the first bonding portion is located closer to the first intersection point than the second bonding portion, and
as viewed in the first direction, an area of the first bonding portion is larger than an area of the second bonding portion.

6. The semiconductor device according to claim 3,
wherein the first bonding portion and the second bonding portion are adjacent to each other, and
the bonding layer includes a third bonding portion spaced apart from the first bonding portion and the second bonding portion in a direction orthogonal to the first direction.

7. The semiconductor device according to claim 6,
wherein the third bonding portion is located adjacent to the first bonding portion and the second bonding portion in a direction perpendicular to the first direction, and
as viewed in the first direction, a virtual line passing through a center of the third bonding portion and extending in a third direction orthogonal to both the first direction and the second direction overlaps the void portion located between the first bonding portion and the second bonding portion.

8. The semiconductor device according to claim 6,
wherein the third bonding portion is located adjacent to the first bonding portion in a third direction orthogonal to both the first direction and the second direction, and
as viewed in the first direction, a virtual line passing through a center of the third bonding portion and extending in the third direction overlaps the first bonding portion.

9. The semiconductor device according to claim 6, wherein as viewed in the first direction, areas of the first bonding portion, the second bonding portion, and the third bonding portion are equal to one another.

10. The semiconductor device according to claim 3, wherein the second bonding portion surrounds the first bonding portion.

11. The semiconductor device according to claim 10, wherein a dimension of the first bonding portion in the second direction is larger than a dimension of the second bonding portion in the second direction.

12. The semiconductor device according to claim 3,
wherein the bonding layer includes a connecting portion connecting the first bonding portion and the second bonding portion, and
a dimension of the connecting portion in the second direction is greater than a dimension of each of the first bonding portion and the second bonding portion in the second direction.

13. The semiconductor device according to claim 12, wherein as viewed in the first direction, the first semiconductor element overlaps the connecting portion.

14. The semiconductor device according to claim 3,
wherein the base material includes an insulating layer located on a side opposite to the heat dissipation member with respect to the heat dissipation layer, and
the first conductive layer is bonded to the insulating layer.

15. The semiconductor device according to claim 14, further comprising:
a second conductive layer positioned on the same side as the first conductive layer with respect to the base material and bonded to the insulating layer; and
a second semiconductor element conductively bonded to the second conductive layer,
wherein the first semiconductor element is conductively bonded to the first conductive layer, and
the second semiconductor element is conductively connected to the first semiconductor element.

16. The semiconductor device according to claim 15, wherein the metal particles contain silver.

17. A method for manufacturing a semiconductor device, comprising:
a first step of bonding a first conductive layer to a base material including a heat dissipation layer such that the first conductive layer is positioned on a side of the base material opposite to the heat dissipation layer in a first direction;
a second step of conductively bonding a first semiconductor element to the first conductive layer;
a third step of placing a bonding material on one side, in the first direction, of either a heat dissipation member or the heat dissipation layer; and
a fourth step of bonding the heat dissipation member to the heat dissipation layer by sintering the bonding material,
wherein the bonding material includes metal particles, and
in the third step, the bonding material is provided with a void portion penetrating the bonding material in the first direction.

18. The method according to claim 17,
wherein in the third step, the bonding material is arranged to include a first portion and a second portion spaced apart from each other in a direction orthogonal to the first direction, and
in the third step, the void portion is formed so as to be exposed to the outside of the bonding material in a direction orthogonal to the first direction.

19. An inverter device, comprising:
a heat dissipation member;
a base material including a heat dissipation layer facing the heat dissipation member in a first direction;
a first conductive layer and a second conductive layer positioned on a side opposite to the heat dissipation member with respect to the base material and bonded to the base material;
a first semiconductor element conductively bonded to the first conductive layer;
a second semiconductor element conductively bonded to the second conductive layer;
a first signal terminal conductively connected to the first semiconductor element;
a second signal terminal conductively connected to the second semiconductor element;
a wiring substrate conductively connected individually to the first signal terminal and the second signal terminal; and
a bonding layer bonding the heat dissipation member to the heat dissipation layer,
wherein the bonding layer includes a sintered body of metal particles, and
the bonding layer is provided with a void portion penetrating the bonding layer in the first direction.

20. A vehicle comprising:
a drive source; and
the semiconductor device according to claim 15,
wherein the semiconductor device is conductively connected to the drive source.
